(19) United States
(12) Patent Application Publication
(10) Pub. No.: US 2022/0406783 A1
(43) Pub. Date: Dec. 22, 2022

(54) SEMICONDUCTOR MEMORY DEVICE

(71) Applicant: Kioxia Corporation, Tokyo (JP)

(72) Inventors: Masaharu WADA, Yokohama (JP); Mutsumi OKAJIMA, Yokkaichi (JP)

(73) Assignee: Kioxia Corporation, Tokyo (JP)

(21) Appl. No.: 17/547,710

(22) Filed: Dec. 10, 2021

(30) Foreign Application Priority Data
Jun. 21, 2021 (JP) 2021-102804

(51) Int. Cl. H01L 27/108; H01L 29/221; G11C 5/02

(52) U.S. Cl. CPC H01L 27/10805; H01L 29/221; G11C 5/025

(57) ABSTRACT

A semiconductor memory device includes a substrate, memory layers, a first wiring disposed at a position closer to the substrate than memory layers or a position farther from the substrate than memory layers, a transistor layer disposed between memory layers and the first wiring, and a second wiring connected to the memory layers and the transistor layer. Each of memory layers includes a memory unit, a first semiconductor layer connected between the memory unit and the second wiring, a first electrode opposed to the first semiconductor layer, a third wiring connected to the first electrode, a second semiconductor layer electrically connected to one end portion of the third wiring, and a second electrode opposed to the second semiconductor layer. The transistor layer includes a third semiconductor layer connected between the first wiring and the second wiring, and a third electrode opposed to the third semiconductor layer.

### CROSS-REFERENCE TO RELATED APPLICATIONS

This application is based upon and claims the benefit of Japanese Patent Application No. 2021-102804, filed on Jun. 21, 2021, the entire contents of which are incorporated herein by reference.

### BACKGROUND

### Field

Embodiments described herein relate generally to a semiconductor memory device.

### Description of the Related Art

In association with high integration of semiconductor memory devices, three-dimensional semiconductor memory devices have been examined.

### BRIEF DESCRIPTION OF THE DRAWINGS

FIG. 1 is a schematic circuit diagram illustrating a configuration of a semiconductor memory device according to a first embodiment;

FIG. 2 is a schematic circuit diagram for describing a read operation of the semiconductor memory device;

FIG. 3 is a schematic waveform diagram for describing the read operation of the semiconductor memory device;

FIG. 4 is a schematic waveform diagram for describing the read operation of the semiconductor memory device;

FIG. 5 is a schematic perspective view illustrating a part of the configuration of the semiconductor memory device;

FIG. 6 is a schematic X-Y cross-sectional view illustrating a part of the configuration of the semiconductor memory device;

FIG. 7 is a schematic X-Y cross-sectional view illustrating a part of the configuration of the semiconductor memory device;

FIG. 8 is a schematic X-Y cross-sectional view illustrating a part of the configuration of the semiconductor memory device;

FIG. 9 is a schematic X-Z cross-sectional view of the configuration illustrated in FIG. 7 and FIG. 8 taken along a line A-A′ viewed in an arrow direction;

FIG. 10 is a schematic Y-Z cross-sectional view of the configuration illustrated in FIG. 7 and FIG. 8 taken along a line B-B′ viewed in an arrow direction;

FIG. 11 is a schematic X-Z cross-sectional view of the configuration illustrated in FIG. 7 and FIG. 8 taken along a line C-C′ viewed in an arrow direction;

FIG. 12 is a schematic cross-sectional view for describing a method for manufacturing the semiconductor memory device according to the first embodiment;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method:

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic X-Z cross-sectional view illustrating a part of a configuration of a semiconductor memory device according to a second embodiment;

FIG. 68 is a schematic cross-sectional view for describing a method for manufacturing the semiconductor memory device according to the second embodiment;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method; and

FIG. 75 is a schematic perspective view illustrating a configuration of a semiconductor memory device according to another embodiment.

### DETAILED DESCRIPTION

A semiconductor memory device according to one embodiment comprises: a substrate; a plurality of memory layers arranged in a first direction intersecting with a surface of the substrate; a first wiring disposed at a position closer to the substrate than the plurality of memory layers or a position farther from the substrate than the plurality of memory layers; a transistor layer disposed between the plurality of memory layers and the first wiring; and a second wiring that extends in the first direction and is connected to the plurality of memory layers and the transistor layer. Each of the plurality of memory layers includes a memory unit, a first semiconductor layer electrically connected between the memory unit and the second wiring, a first electrode opposed to the first semiconductor layer, a third wiring that extends in a second direction intersecting with the first direction and is connected to the first electrode, a second semiconductor layer electrically connected to one end portion in the second direction of the third wiring, and a second electrode opposed to the second semiconductor layer. The transistor layer includes a third semiconductor layer electrically connected between the first wiring and the second wiring, and a third electrode opposed to the third semiconductor layer.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, or the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

### First Embodiment

### Circuit Configuration

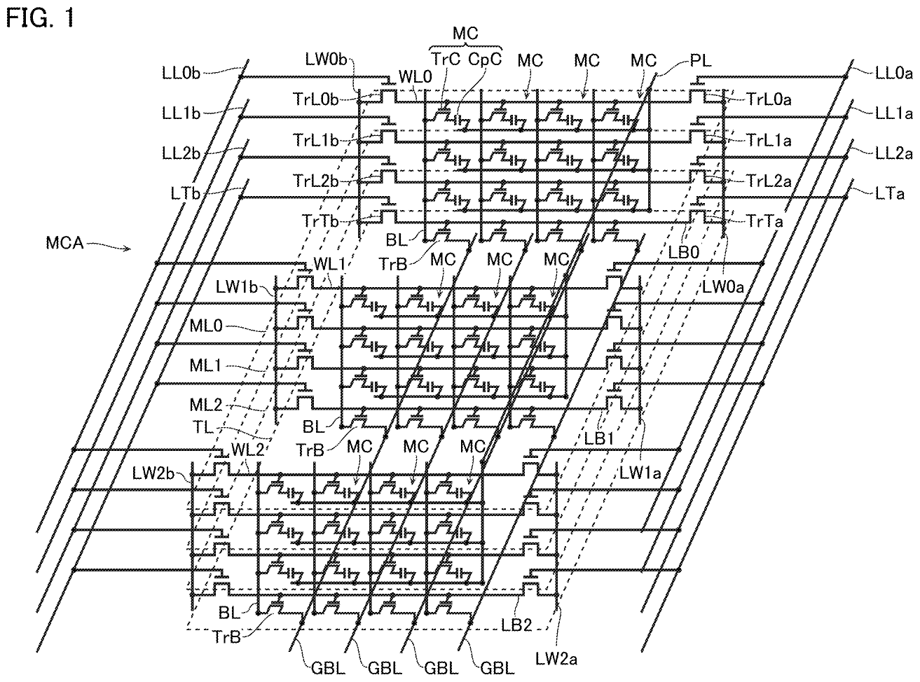

FIG. 1 is a schematic circuit diagram illustrating a configuration of a semiconductor memory device according to the first embodiment. As illustrated in FIG. 1, the semiconductor memory device according to the embodiment includes a memory cell array MCA. The memory cell array MCA includes a plurality of memory layers ML0 to ML2, a transistor layer TL, a plurality of bit lines BL connected to these plurality of memory layers ML0 to ML2 and the transistor layer TL, a plurality of global bit lines GBL electrically connected to the plurality of bit lines BL via the transistor layer TL, and a plate line PL connected to the plurality of memory layers ML0 to ML2.

The memory layers ML0 to ML2 each include a plurality of word lines WL0 to WL2 and a plurality of memory cells MC connected to these plurality of word lines WL0 to WL2. Each of the plurality of memory cells MC includes a transistor TrC and a capacitor CpC. The transistor TrC has a source electrode connected to the bit line BL. The transistor TrC has a drain electrode connected to the capacitor CpC. The transistor TrC has a gate electrode connected to any of the word lines WL0 to WL2. One electrode of the capacitor CpC is connected to the drain electrode of the transistor TrC. The other electrode of the capacitor CpC is connected to the plate line PL.

Each of the bit lines BL is connected to a plurality of the memory cells MC corresponding to the plurality of memory layers ML0 to ML2.

The memory layers ML0 to ML2 respectively include a plurality of transistors TrL0a and TrL0b, TrL1a and TrL1b, and TrL2a and TrL2b (hereinafter referred to as “transistor TrL” in some cases) disposed corresponding to each of a plurality of the word lines WL0 to WL2. Drain electrodes of the transistors TrL are each connected to any of the word lines WL0 to WL2. Source electrodes of the transistors TrL are each connected to any of word line select lines LW0a, LW0b, LW1a, LW1b, LW2a, and LW2b (hereinafter referred to as “word line select line LW” in some cases). Gate electrodes of the transistors TrL are each connected to any of layer select lines LL0a, LL0b, LL1a, LL1b, LL2a, and LL2b (hereinafter referred to as “layer select line LL” in some cases).

The word line select line LW is connected to a plurality of the transistors TrL corresponding to a plurality of the memory layers ML0 to ML2. The layer select lines LL0a, LL1a, and LL2a are respectively connected commonly to all of the transistors TrL0a, TrL1a, and TrL2a corresponding to the memory layers ML0 to ML2. Similarly, the layer select lines LL0b, LL1b, and LL2b are respectively connected commonly to all of the transistors TrL0b, TrL1b, and TrL2b corresponding to the memory layers ML0 to ML2.

The transistor layer TL includes a plurality of bit line select lines LB0 to LB2 and a plurality of transistors TrB connected to the plurality of bit line select lines LB0 to LB2. Source electrodes of the transistors TrB are each connected to the global bit line GBL. Drain electrodes of the transistors TrB are each connected to the bit line BL. Gate electrodes of the transistors TrB are each connected to any of the bit line select lines LB0 to LB2.

The transistor layer TL includes a plurality of transistors TrTa, TrTb (hereinafter referred to as “transistor TrT” in some cases) each disposed corresponding to the plurality of bit line select lines LB0 to LB2. Drain electrodes of the transistor TrT are each connected to any of the bit line select lines LB0 to LB2. Source electrodes of the transistors TrT are each connected to the word line select line LW. Gate electrodes of the transistors TrT are each connected to any of wirings LTa, LTb (hereinafter referred to as “wiring LT” in some cases).

The wiring LTa is connected to all of the transistors TrTa in common. Similarly, the wiring LTb is connected to all of the transistors TrTb in common.

### Read Operation

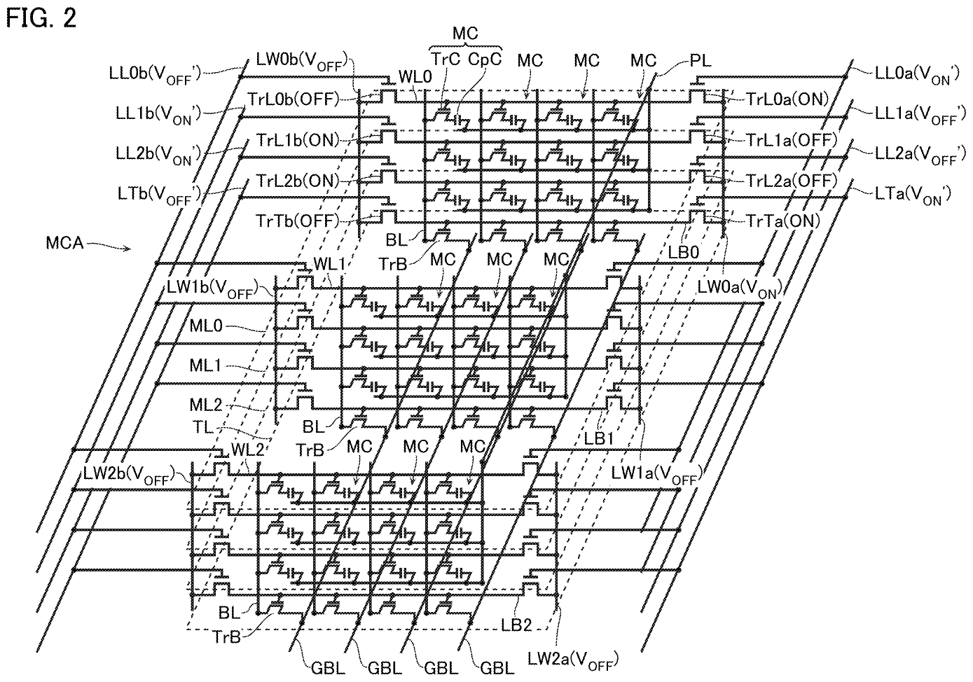

FIG. 2 is a schematic circuit diagram for describing a read operation of the semiconductor memory device according to the first embodiment.

In the read operation, one of the plurality of memory layers ML0 to ML2 is selected. In the illustrated example, the memory layer ML0 is selected. In the selection of the memory layers ML0 to ML2, for example, a voltage V_{ON}′ is applied to the layer select line LL0a corresponding to the memory layer ML0 as a target of the read operation among the plurality of layer select lines LL0a, LL1a, and LL2a, and a voltage V_{OFF}′ is applied to the other layer select lines LL1a and LL2a. For example, the voltage V_{OFF}′ is applied to the layer select line LL0b corresponding to the memory layer ML0 as a target of the read operation among the plurality of layer select lines LL0b, LL1b, and LL2b, and the voltage V_{ON}′ is applied to the other layer select lines LL1b and LL2b. The voltage V_{ON}′ is applied to the wiring LTa and the voltage V_{OFF}′ is applied to the wiring LTb.

The voltage V_{ON}′ has a magnitude, for example, enough to turn ON the transistors TrL, TrT. The voltage V_{OFF}′ has a magnitude, for example, enough to turn OFF the transistors TrL, TrT. For example, when the transistors TrL, TrT are NMOS transistors, the voltage V_{ON}′ is larger than the voltage V_{OFF}′. For example, when the transistors TrL, TrT are PMOS transistors, the voltage V_{ON}′ is smaller than the voltage V_{OFF}′.

In the read operation, one of the plurality of word lines WL0 to WL2 is selected. In the illustrated example, the word line WL0 is selected. In the selection of the word lines WL0 to WL2, for example, a voltage V_{ON} is applied to the word line select line LW0a corresponding to the word line WL0 as a target of the read operation among the plurality of word line select lines LW0a, LW1a, and LW2a, and a voltage V_{OFF} is applied to the other layer select lines LW1a, LW2a. For example, the voltage V_{OFF} is applied to the plurality of word line select lines LW0b, LW1b, and LW2b.

The voltage V_{ON} has a magnitude, for example, enough to turn ON the transistors TrC, TrB. The voltage V_{OFF} has a magnitude, for example, enough to turn OFF the transistors TrC, TrB. For example, when the transistors TrC, TrB are NMOS transistors, the voltage V_{ON} is larger than the voltage V_{OFF}. For example, when the transistors TrC, TrB are PMOS transistors, the voltage V_{ON} is smaller than the voltage V_{OFF}. Here, the voltage V_{ON} is applied to the word line WL0 (hereinafter referred to as “selected word line WL0”) connected to the memory cell MC (hereinafter referred to as “selected memory cell MC”) as a target of the read operation via the transistor TrL0a. Accordingly, the transistor TrC in the selected memory cell MC turns ON. The voltage V_{ON} is applied to the transistor TrB connected to the selected memory cell MC via the transistor TrTa. Accordingly, the transistors TrB turn ON, thereby electrically conducting the capacitor CpC in the selected memory cell MC to the global bit line GBL. In association with this, a voltage of the global bit line GBL fluctuates, or a current flows in the global bit line GBL. By detecting this voltage fluctuation or current, data stored in the selected memory cell MC can be read out.

The voltage V_{OFF} is applied to the word lines WL1, WL2 (hereinafter referred to as “unselected word lines WL1, WL2” or the like) other than the selected word line WL0 corresponding to the memory layer ML0 the same as the selected memory cell MC via the transistors TrL0a. Accordingly, the transistors TrC in the memory cells MC turn OFF. The voltage V_{OFF} is applied to the transistors TrB connected to such memory cells MC via the transistors TrTa. Accordingly, the transistors TrB turn OFF.

The voltage V_{OFF} is applied to the unselected word lines WL0, WL1, and WL2 corresponding to the memory layers ML1 and ML2 different from the selected memory cell MC via the transistors TrL1b and TrL2b. Accordingly, the transistors TrC in the memory cells MC turn OFF.

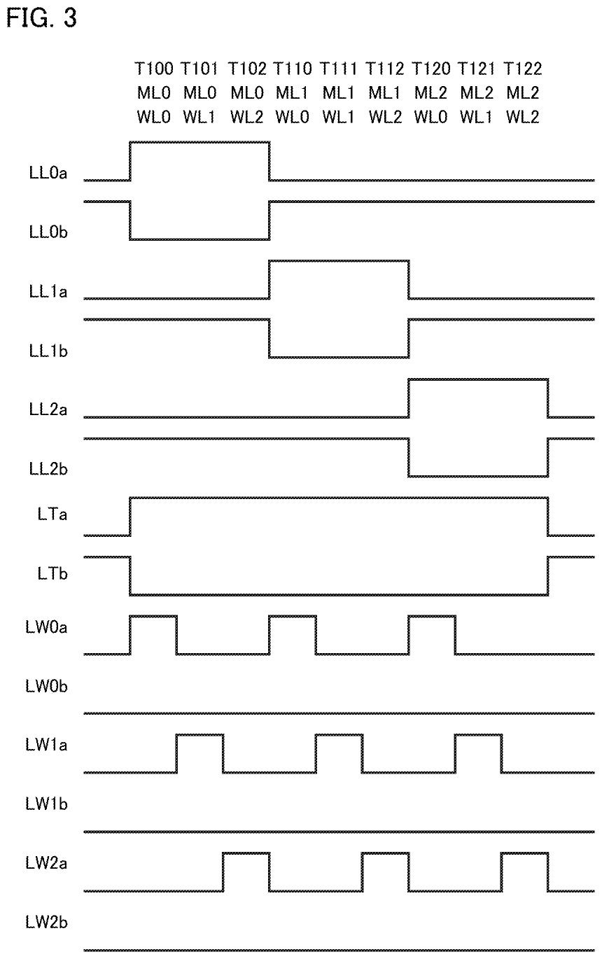

FIG. 3 is a schematic waveform diagram for describing an example of executing the read operation. In the example of FIG. 3, the read operations corresponding to the plurality of word lines WL0 to WL2 included in the memory layer ML0 are sequentially executed, the read operations corresponding to the plurality of word lines WL0 to WL2 included in the memory layer ML1 are sequentially executed, and further, the read operations corresponding to the plurality of word lines WL0 to WL2 included in the memory layer ML2 are sequentially executed.

That is, in the example of FIG. 3, the read operation on the plurality of memory cells MC connected to the word line WL0 included in the memory layer ML0 is executed in a time period T100. The read operation on the plurality of memory cells MC connected to the word line WL1 included in the memory layer ML0 is executed in a time period T101. The read operation on the plurality of memory cells MC connected to the word line WL2 included in the memory layer ML0 is executed in a time period T102.

The read operation on the plurality of memory cells MC connected to the word line WL0 included in the memory layer ML1 is executed in a time period T110. The read operation on the plurality of memory cells MC connected to the word line WL1 included in the memory layer ML1 is executed in a time period T111. The read operation on the plurality of memory cells MC connected to the word line WL2 included in the memory layer ML1 is executed in a time period T112.

The read operation on the plurality of memory cells MC connected to the word line WL0 included in the memory layer ML2 is executed in a time period T120. The read operation on the plurality of memory cells MC connected to the word line WL1 included in the memory layer ML2 is executed in a time period T121. The read operation on the plurality of memory cells MC connected to the word line WL2 included in the memory layer ML2 is executed in a time period T122.

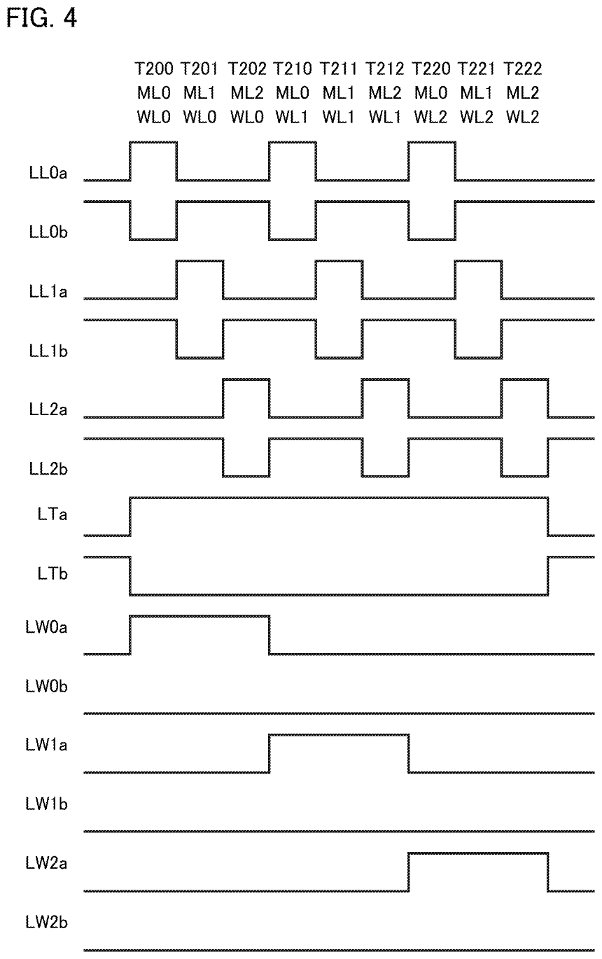

FIG. 4 is a schematic waveform diagram for describing another example of executing the read operation. In the example of FIG. 4, the read operations corresponding to the word lines WL0 included in the respective memory layers ML0 to ML2 are sequentially executed, the read operations corresponding to the word lines WL1 included in the respective memory layers ML0 to ML2 are sequentially executed, and further, the read operations corresponding to the word lines WL2 included in the respective memory layers ML0 to ML2 are sequentially executed.

That is, in the example of FIG. 4, the read operation on the plurality of memory cells MC connected to the word line WL0 included in the memory layer ML0 is executed in a time period T200. The read operation on the plurality of memory cells MC connected to the word line WL0 included in the memory layer ML1 is executed in a time period T201. The read operation on the plurality of memory cells MC connected to the word line WL0 included in the memory layer ML2 is executed in a time period T202.

The read operation on the plurality of memory cells MC connected to the word line WL1 included in the memory layer ML0 is executed in a time period T210. The read operation on the plurality of memory cells MC connected to the word line WL1 included in the memory layer ML1 is executed in a time period T211. The read operation on the plurality of memory cells MC connected to the word line WL1 included in the memory layer ML2 is executed in a time period T212.

The read operation on the plurality of memory cells MC connected to the word line WL2 included in the memory layer ML0 is executed in a time period T220. The read operation on the plurality of memory cells MC connected to the word line WL2 included in the memory layer ML1 is executed in a time period T221. The read operation on the plurality of memory cells MC connected to the word line WL2 included in the memory layer ML2 is executed in a time period T222.

FIG. 3 and FIG. 4 illustrate an example in which the voltage is applied to the word lines WL0 to WL2 in the memory layers ML0 to ML2 as the targets of the read operations via the transistors TrL0a, TrL1a, and TrL2a. FIG. 3 and FIG. 4 illustrate the example in which the voltage is applied to the other word lines WL0 to WL2 in the memory layers ML0 to ML2 via the transistors TrL0b, TrL1b, and TrL2b. However, for example, the voltage applied to the transistors TrL0a, TrL1a, and TrL2a in the example of FIG. 3 and FIG. 4 may be applied to the transistors TrL0b, TrL1b, and TrL2b, and the voltage applied to the transistors TrL0b, TrL1b, and TrL2b in the example of FIG. 3 and FIG. 4 may be applied to the transistors TrL0a, TrL1a, and TrL2a.

### Structure

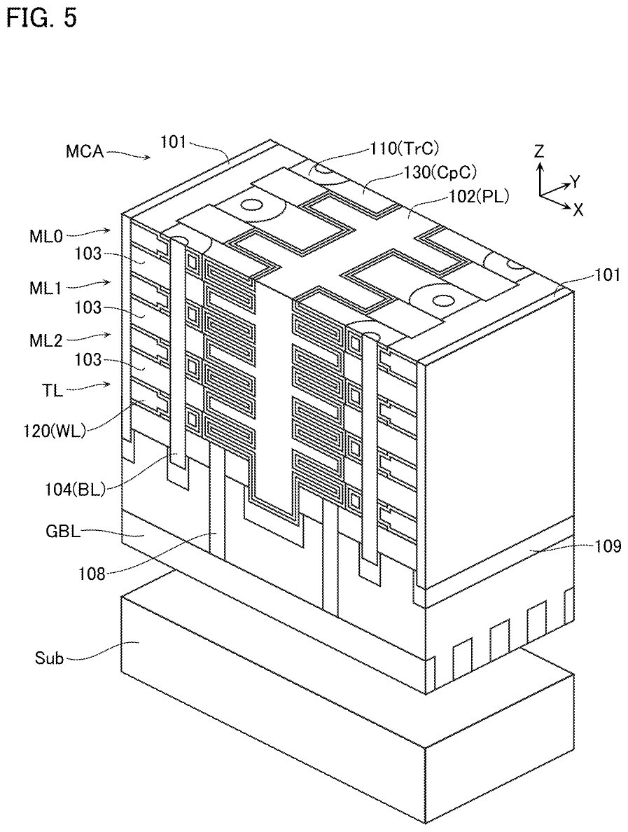

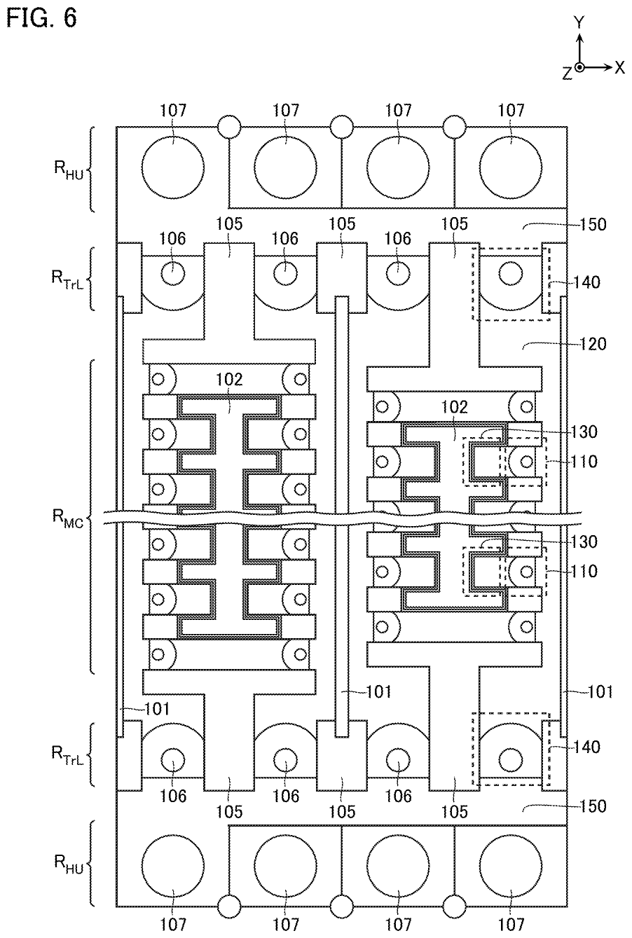

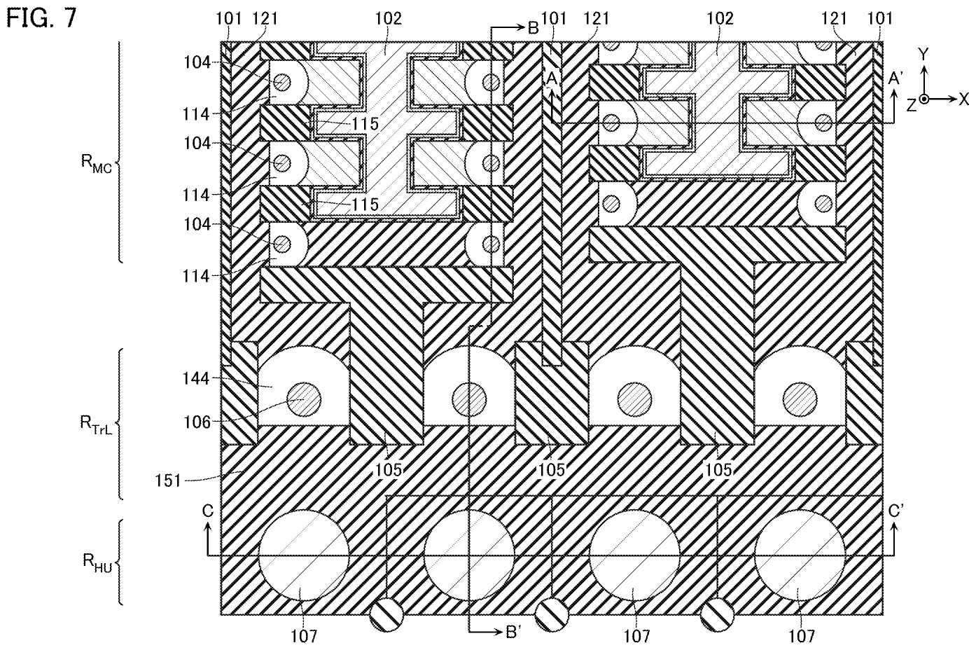

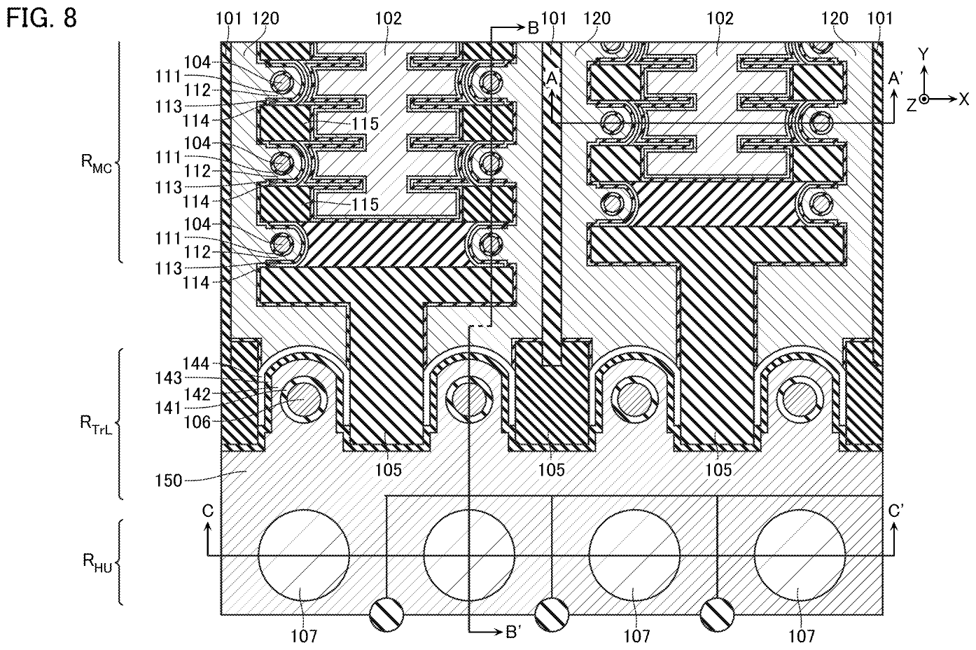

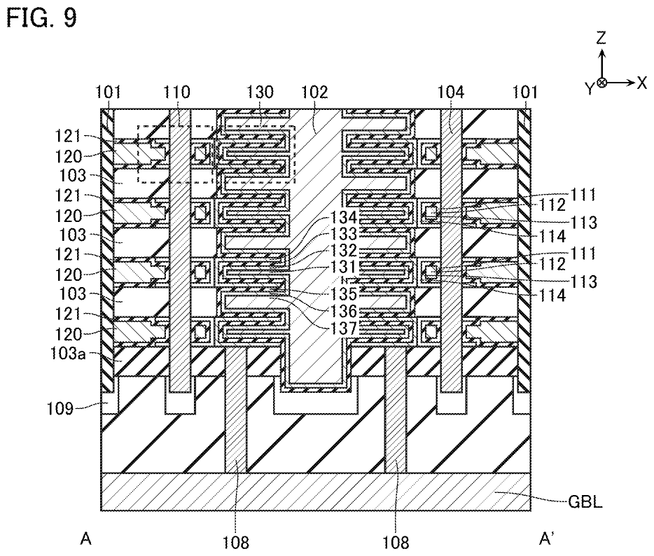

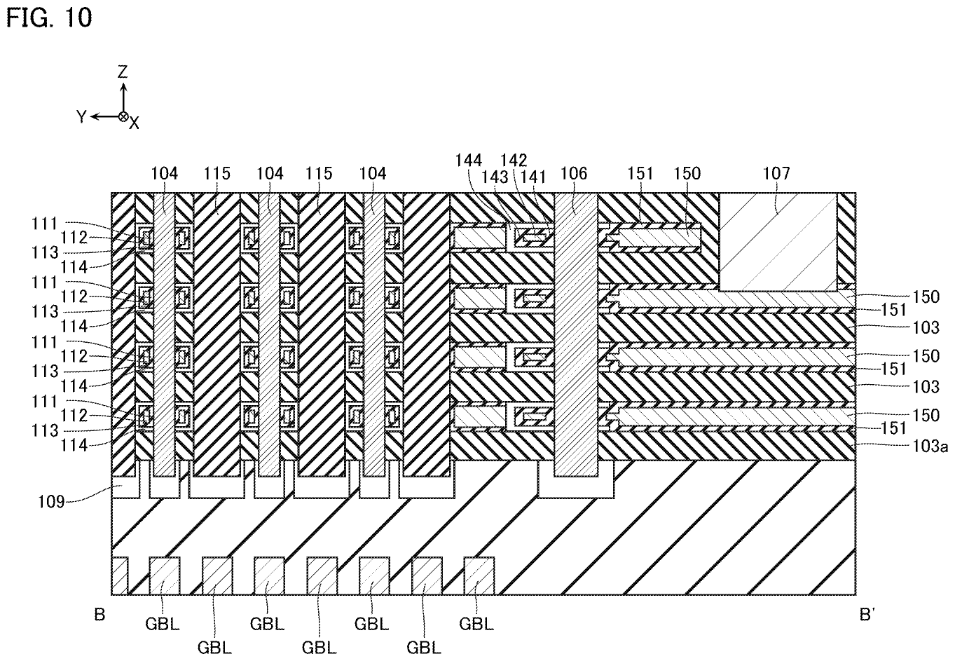

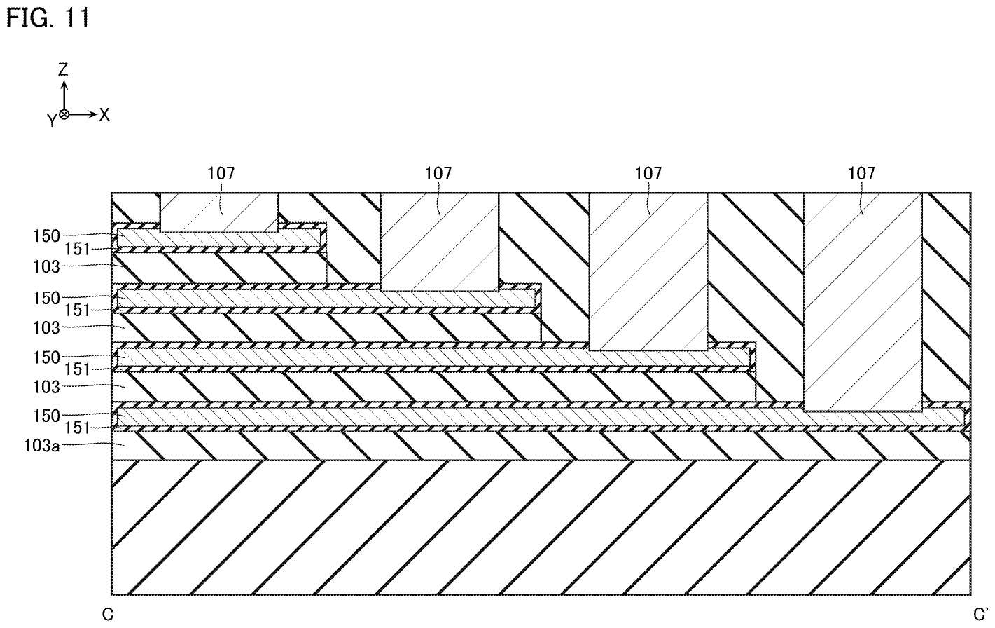

FIG. 5 is a schematic perspective view illustrating a part of the configuration of the semiconductor memory device according to the first embodiment. FIG. 6 is a schematic X-Y cross-sectional view illustrating a part of the configuration of the semiconductor memory device. In FIG. 6, a part of the configuration (insulating layers 121, 151 described later) is omitted. FIG. 7 and FIG. 8 are schematic X-Y cross-sectional views illustrating a part of the configuration of the semiconductor memory device. FIG. 7 and FIG. 8 illustrate the X-Y cross-sectional surfaces at different height positions. FIG. 9 is a schematic X-Z cross-sectional view of the configuration illustrated in FIG. 7 and FIG. 8 taken along a line A-A′ viewed in an arrow direction. FIG. 10 is a schematic Y-Z cross-sectional view of the configuration illustrated in FIG. 7 and FIG. 8 taken along a line B-B′ viewed in an arrow direction. FIG. 11 is a schematic X-Z cross-sectional view of the configuration illustrated in FIG. 7 and FIG. 8 taken along a line C-C′ viewed in an arrow direction.

FIG. 5 illustrates a part of a semiconductor substrate Sub and the memory cell array MCA disposed above the semiconductor substrate Sub.

The semiconductor substrate Sub is, for example, a semiconductor substrate of silicon (Si) or the like containing P-type impurities, such as boron (B). An insulating layer and an electrode layer (not illustrated) are disposed on an upper surface of the semiconductor substrate Sub. The upper surface of the semiconductor substrate Sub and the not illustrated insulating layer and electrode layer constitute a control circuit for controlling the semiconductor memory device according to the first embodiment. For example, in a region immediately below the memory cell array MCA, a sense amplifier circuit is disposed. The sense amplifier circuit is connected to the global bit lines GBL. The sense amplifier circuit can read out the data stored in the selected memory cell MC by detecting the voltage fluctuation or the current in the global bit line GBL in the read operation.

The memory cell array MCA includes the plurality of memory layers ML0 to ML2 arranged in the Z-direction, the transistor layer TL disposed below them, and a plurality of global bit lines GBL disposed below it. Insulating layers 103 of silicon oxide (SiO₂) or the like are each disposed between the plurality of memory layers ML0 to ML2.

As illustrated in FIG. 6, the memory layers ML0 to ML2 each include a memory cell region R_{MC}, and transistor regions R_{TrL} and hook-up regions R_{HU} each disposed on one side and the other side of the memory cell region R_{MC} in the Y-direction. Each of the transistor regions R_{TrL} is disposed between the memory cell region R_{MC} and the hook-up region R_{HU}.

In the memory cell region R_{MC}, a plurality of insulating layers 101 and a plurality of conductive layers 102 alternately arranged in the X-direction are disposed. As illustrated in FIG. 5, these plurality of insulating layers 101 and plurality of conductive layers 102 extend in the Y-direction and the Z-direction, and separate the memory layers ML0 to ML2 and the transistor layer TL in the X-direction.

The insulating layer 101 contains, for example, silicon oxide (SiO₂).

The conductive layer 102 has, for example, a stacked structure of titanium nitride (TiN) and tungsten (W). The conductive layer 102 functions as, for example, the plate line PL (FIG. 1).

The memory cell region R_{MC} includes a plurality of conductive layers 104 disposed between the insulating layers 101 and the conductive layers 102. The plurality of conductive layers 104 are arranged in the Y-direction, and penetrate the plurality of memory layers ML0 to ML2 and the transistor layer TL to extend in the Z-direction.

The conductive layer 104 has, for example, a stacked structure of indium tin oxide (ITO), titanium nitride (TiN), and tungsten (W). The conductive layer 104 functions as, for example, a bit line BL (FIG. 1). A plurality of the bit lines BL are disposed corresponding to the plurality of transistors TrC included in the memory layers ML0 to ML2. In the memory cell region R_{MC}, the memory layers ML0 to ML2 each include a plurality of transistor structures 110 disposed corresponding to the plurality of conductive layers 104, conductive layers 120 disposed between the plurality of transistor structures 110 and the insulating layers 101, and a plurality of capacitor structures 130 disposed between the plurality of transistor structures 110 and the conductive layers 102.

For example, as illustrated in FIG. 8 and FIG. 9, the transistor structure 110 includes an insulating layer 111 disposed on an outer peripheral surface of the conductive layer 104, a conductive layer 112 disposed on an outer peripheral surface of the insulating layer 111, an insulating layer 113 disposed on an upper surface, a lower surface, and an outer peripheral surface of the conductive layer 112, and a semiconductor layer 114 disposed on an upper surface, a lower surface, and an outer peripheral surface of the insulating layer 113.

In the X-Y cross-sectional surface as illustrated in FIG. 8, the outer peripheral surface of the insulating layer 111 may be formed along, for example, a circle having a center position of the conductive layer 104 as the center. Side surfaces of the conductive layer 112, the insulating layer 113, and the semiconductor layer 114 on one side (the conductive layer 102 side) in the X-direction may be formed along a circle having the center position of the conductive layer 104 as the center. Both side surfaces of the conductive layer 112, the insulating layer 113, and the semiconductor layer 114 in the Y-direction may be formed linearly along side surfaces of the insulating layers 115.

The insulating layer 111 contains silicon oxide (SiO₂) or the like. The insulating layer 111 surrounds the outer peripheral surface of the conductive layer 104 over the whole circumference.

The conductive layer 112 functions as, for example, the gate electrode of the transistor TrC (FIG. 1). The conductive layer 112 has, for example, a stacked structure of titanium nitride (TiN) and tungsten (W). The conductive layer 112 surrounds the outer peripheral surface of the insulating layer 111 over the whole circumference. As illustrated in FIG. 8, a plurality of the conductive layers 112 arranged in the Y-direction are commonly connected to the conductive layer 120 extending in the Y-direction.

The insulating layer 113 functions as, for example, a gate insulating film of the transistor TrC (FIG. 1). The insulating layer 113 contains silicon oxide (SiO₂) or the like. The insulating layer 113 covers both side surfaces in the Y-direction and the side surface on one side (the conductive layer 102 side) in the X-direction of the conductive layer 112.

The semiconductor layer 114 functions as, for example, a channel region of the transistor TrC (FIG. 1). For example, the semiconductor layer 114 may be a semiconductor containing at least one element of gallium (Ga) and aluminum (Al), and containing indium (In), zinc (Zn), and oxygen (O), or may be another oxide semiconductor. The semiconductor layer 114 covers both side surfaces in the Y-direction and the side surface on one side (the conductive layer 102 side) in the X-direction of the conductive layer 112 via the insulating layer 113. As illustrated in FIG. 9, the plurality of semiconductor layers 114 arranged in the Z-direction are commonly connected to the conductive layer 104 extending in the Z-direction. As illustrated in FIG. 7, an insulating layer 115 of silicon oxide (SiO₂) or the like is disposed between the two semiconductor layers 114 mutually adjacent in the Y-direction.

The conductive layer 120 functions as, for example, the word line WL (FIG. 1). For example, as illustrated in FIG. 8, the conductive layer 120 extends in the Y-direction, and is connected to the plurality of conductive layers 112 arranged in the Y-direction. The conductive layer 120 has, for example, a stacked structure of titanium nitride (TiN) and tungsten (W). An upper surface and a lower surface of the conductive layer 120 are covered with an insulating layer 121 of silicon oxide (SiO₂) or the like. The insulating layer 121 is connected to the insulating layer 111 and the insulating layer 113.

For example, as illustrated in FIG. 9, the capacitor structure 130 includes a conductive layer 131, a conductive layer 132 disposed on an upper surface, a lower surface, and a side surface in the Y-direction of the conductive layer 131, an insulating layer 133 disposed on an upper surface, a lower surface, and a side surface in the Y-direction of the conductive layer 132, a conductive layer 134 disposed on an upper surface, a lower surface, and a side surface in the Y-direction of the insulating layer 133, an insulating layer 135 disposed on an upper surface, a lower surface, and a side surface in the Y-direction of the conductive layer 134, a conductive layer 136 disposed on an upper surface, a lower surface, and a side surface in the Y-direction of the insulating layer 135, and a conductive layer 137 disposed on an upper surface, a lower surface, and a side surface in the Y-direction of the conductive layer 136.

The conductive layers 131, 132, 136, and 137 function as one electrode of the capacitor CpC (FIG. 1). The conductive layers 131, 137 contain tungsten (W) or the like. The conductive layers 132, 136 contain titanium nitride (TiN) or the like. The conductive layers 131, 132, 136, and 137 are connected to the conductive layer 102.

The insulating layers 133, 135 function as an insulating layer of the capacitor CpC (FIG. 2). The insulating layers 133, 135 may be, for example, alumina (Al₂O₃) or another insulating metal oxide.

The conductive layer 134 functions as, for example, the other electrode of the capacitor CpC (FIG. 2). The conductive layer 134 contains indium tin oxide (ITO) or the like. The conductive layer 134 is insulated from the conductive layers 131, 132, 136, and 137 via the insulating layers 133, 135. The conductive layer 134 is connected to a side surface in the X-direction of the semiconductor layer 114.

For example, as illustrated in FIG. 6, the transistor region R_{TrL} includes a plurality of insulating layers 105 arranged in the X-direction. These plurality of insulating layers 105 penetrate the plurality of memory layers ML0 to ML2 and the transistor layer TL, and extend in the Z-direction.

The insulating layer 105 contains silicon oxide (SiO₂) or the like.

The transistor region R_{TrL} includes a plurality of conductive layers 106 disposed between the insulating layers 105. The plurality of conductive layers 106 are arranged in the X-direction, and penetrate the plurality of memory layers ML0 to ML2 and the transistor layer TL to extend in the Z-direction (see FIG. 10).

The conductive layer 106 has, for example, a stacked structure of indium tin oxide (ITO), titanium nitride (TiN), and tungsten (W). The conductive layer 106 functions as, for example, the word line select line LW (FIG. 1). A plurality of the word line select lines LW are disposed corresponding to the plurality of transistors TrL included in the memory layers ML0 to ML2.

For example, as illustrated in FIG. 6, in the transistor region R_{TrL}, the memory layers ML0 to ML2 each include a plurality of transistor structures 140 disposed corresponding to the plurality of conductive layers 106, and a conductive layer 150 extending in the X-direction along these plurality of transistor structures 140.

For example, as illustrated in FIG. 8 and FIG. 10, the transistor structure 140 includes an insulating layer 141 disposed on an outer peripheral surface of the conductive layer 106, a conductive layer 142 disposed on an outer peripheral surface of the insulating layer 141, an insulating layer 143 disposed on an upper surface, a lower surface, and an outer peripheral surface of the conductive layer 142, and a semiconductor layer 144 disposed on an upper surface, a lower surface, and an outer peripheral surface of the insulating layer 143.

In the X-Y cross-sectional surface as illustrated in FIG. 8, the outer peripheral surface of the insulating layer 141 may be formed, for example, along a circle having a center position of the conductive layer 106 as the center. Side surfaces of the conductive layer 142, the insulating layer 143, and the semiconductor layer 144 on one side (the conductive layer 120 side) in the Y-direction may be formed along the circle having the center position of the conductive layer 106 as the center. Both side surfaces in the X-direction of the conductive layer 142, the insulating layer 143, and the semiconductor layer 144 may be formed linearly along side surfaces of the insulating layers 105.

The insulating layer 141 contains silicon oxide (SiO₂) or the like. The insulating layer 141 surrounds the outer peripheral surface of the conductive layer 106 over the whole circumference.

The conductive layer 142 functions as, for example, a gate electrode of the transistor TrL (FIG. 1). The conductive layer 142 has, for example, a stacked structure of titanium nitride (TiN) and tungsten (W). The conductive layer 142 surrounds the outer peripheral surface of the insulating layer 141 over the whole circumference. As illustrated in FIG. 8, a plurality of the conductive layers 142 arranged in the X-direction are commonly connected to the conductive layer 150 extending in the X-direction.

The insulating layer 143 functions as, for example, a gate insulating film of the transistor TrL (FIG. 1). The insulating layer 143 contains silicon oxide (SiO₂) or the like. The insulating layer 143 covers both side surfaces in the X-direction and the side surface on one side (the conductive layer 120 side) in the Y-direction of the conductive layer 142.

The semiconductor layer 144 functions as, for example, a channel region of the transistor TrL (FIG. 1). For example, the semiconductor layer 144 may be a semiconductor containing at least one element of gallium (Ga) and aluminum (Al), and containing indium (In), zinc (Zn), and oxygen (O), or may be another oxide semiconductor. The semiconductor layer 144 covers both side surfaces in the X-direction and the side surface on one side (the conductive layer 120 side) in the Y-direction of the conductive layer 142 via the insulating layer 143. As illustrated in FIG. 10, the plurality of semiconductor layers 144 arranged in the Z-direction are commonly connected to the conductive layer 106 extending in the Z-direction. As illustrated in FIG. 7, the insulating layer 105 is disposed between the two semiconductor layers 144 mutually adjacent in the X-direction. The semiconductor layer 144 is connected to an end portion of the conductive layer 120 in the Y-direction.

The conductive layer 150 functions as, for example, the layer select line LL (FIG. 1). For example, as illustrated in FIG. 8, the conductive layer 150 extends in the X-direction, and is connected to the plurality of conductive layers 142 arranged in the X-direction. The conductive layer 150 has, for example, a stacked structure of titanium nitride (TiN) and tungsten (W). An upper surface and a lower surface of the conductive layer 150 are covered with an insulating layer 151 of silicon oxide (SiO₂) or the like. The insulating layer 151 is connected to the insulating layer 141 and the insulating layer 143.

The hook-up region R_{HU} includes a plurality of contact electrodes 107 arranged in the X-direction. As illustrated in FIG. 11, the contact electrode 107 extends in the Z-direction, and has a lower end connected to the conductive layer 150. The plurality of contact electrodes 107 arranged in the X-direction are connected to the respective conductive layers 150 disposed at different height positions. The contact electrode 107 has, for example, a stacked structure of titanium nitride (TiN) and tungsten (W).

The transistor layer TL is configured similarly to the memory layers ML0 to ML2.

However, the conductive layer 112, the insulating layer 113, and the semiconductor layer 114 in the transistor layer TL respectively function as a gate electrode, a gate insulating film, and a channel region of the transistor TrB. The conductive layers 120 in the transistor layer TL function as the bit line select lines LB0 to LB2. The conductive layer 134 in the transistor layer TL functions as a source electrode of the transistor TrB.

The conductive layer 142, the insulating layer 143, and the semiconductor layer 144 in the transistor layer TL respectively function as a gate electrode, a gate insulating film, and a channel region of the transistor TrT. The conductive layer 150 in the transistor layer TL functions as the wiring LT.

As illustrated in FIG. 5, a plurality of the global bit lines GBL are disposed below the transistor layer TL. The global bit lines GBL extend in the X-direction, and are arranged in the Y-direction. The global bit line GBL has, for example, a stacked structure of titanium nitride (TiN) and tungsten (W).

A plurality of contact electrodes 108 arranged in the X-direction along the global bit lines GBL are disposed in a region between the transistor layer TL and the global bit lines GBL. These plurality of contact electrodes 108 extend in the Z-direction, and have lower ends connected to upper surfaces of the global bit lines GBL. These plurality of contact electrodes 108 have upper ends connected to lower surfaces of the conductive layers 134 in the transistor layer TL (see FIG. 9). The contact electrode 108 has, for example, a stacked structure of titanium nitride (TiN) and tungsten (W).

As illustrated in FIG. 5, etching stoppers 109 are disposed between the transistor layer TL and the plurality of global bit lines GBL. The etching stoppers 109 are disposed corresponding to the insulating layers 101, the conductive layers 102, the conductive layers 104, the insulating layers 105, and the conductive layers 106, and connected to lower ends of them. The etching stoppers 109 have shapes along shapes of the lower ends of the corresponding configurations. For example, the etching stopper 109 corresponding to the insulating layer 101 extends in the Y-direction corresponding to the insulating layer 101. Similarly, the etching stopper 109 corresponding to the conductive layer 102 extends in the Y-direction corresponding to the conductive layer 102.

An insulating layer 103a is disposed between the transistor layer TL and the etching stoppers 109 (see FIG. 9). For example, the insulating layer 103a may contain a material different from that of other insulating layers 103. For example, the insulating layer 103a may contain carbon-containing silicon oxide (SiOC) or the like.

### Manufacturing Method

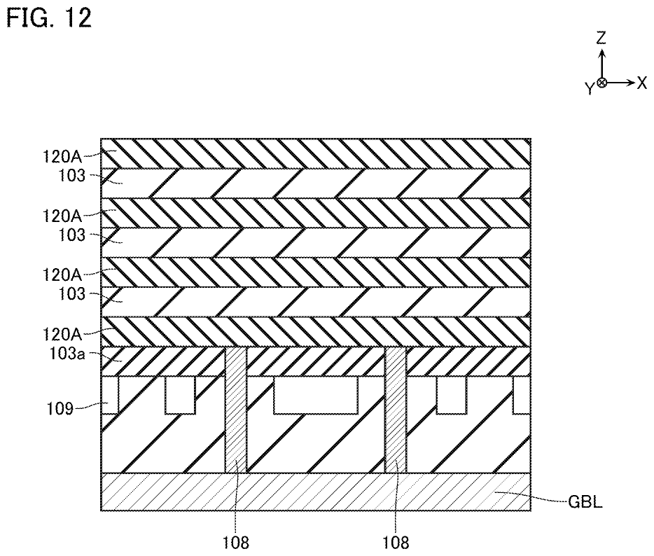

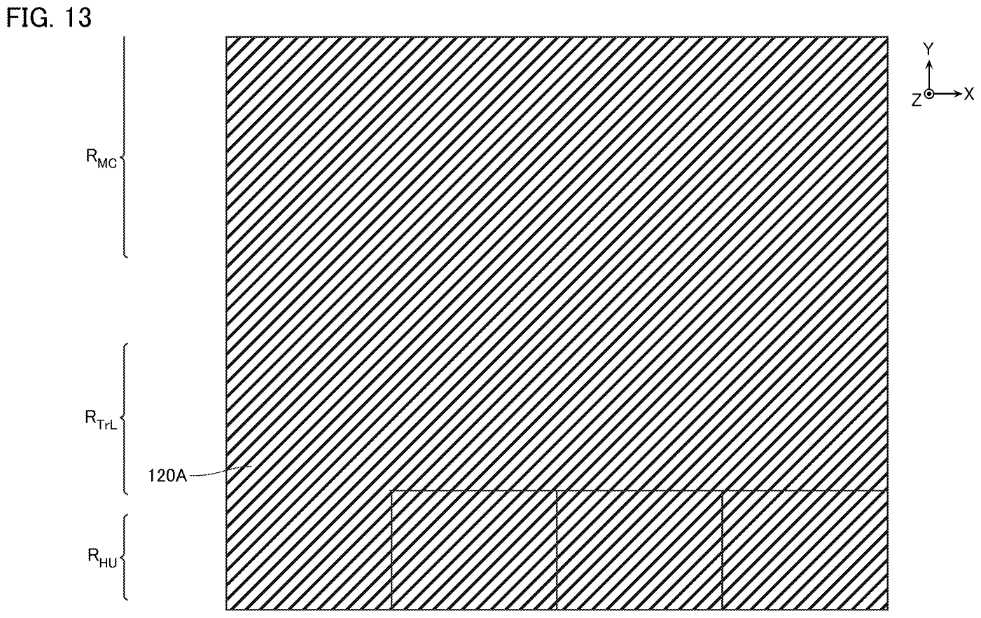

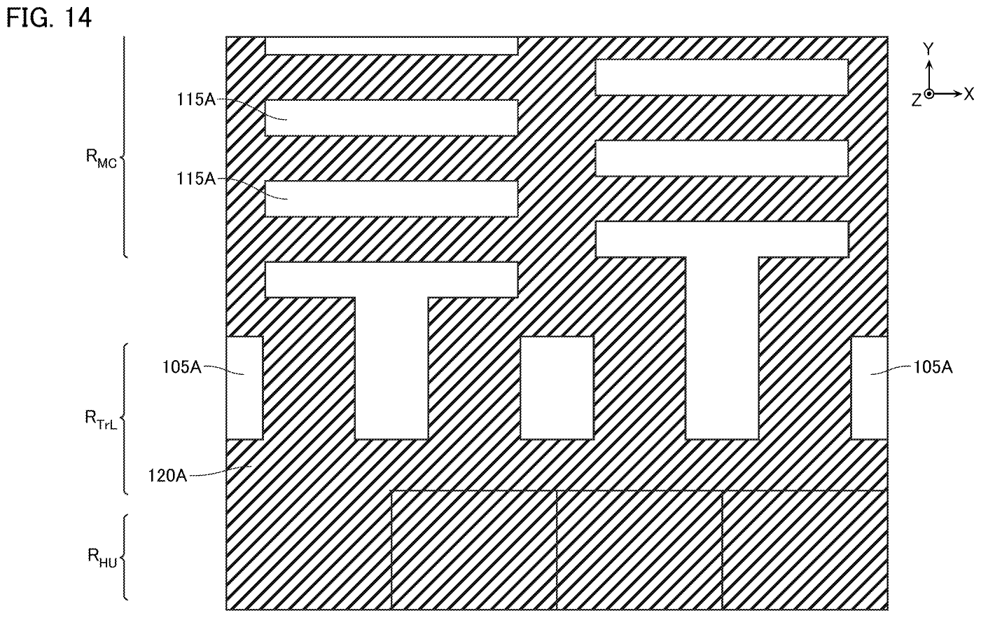

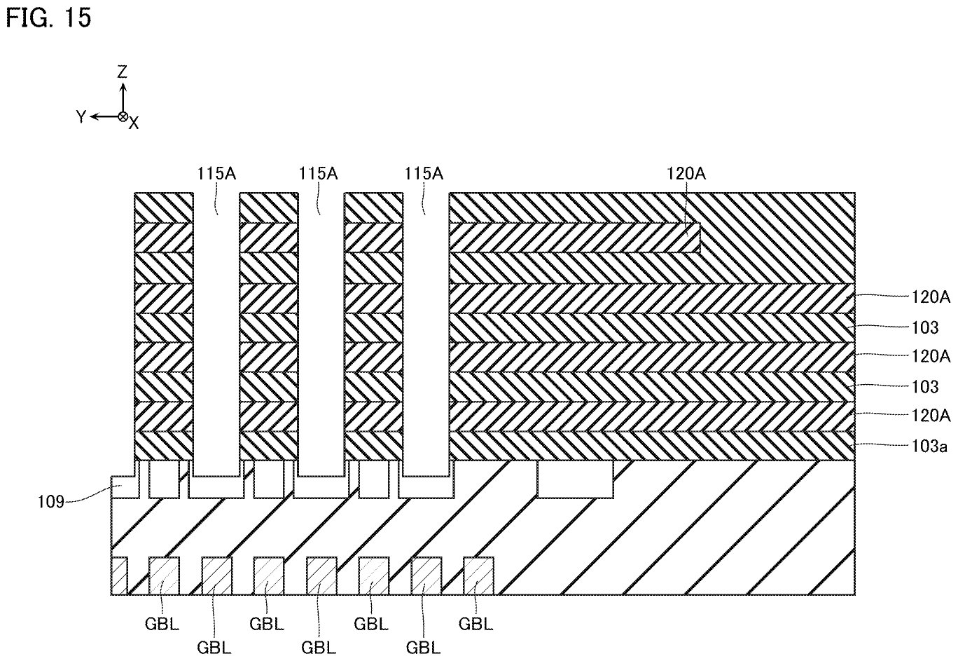

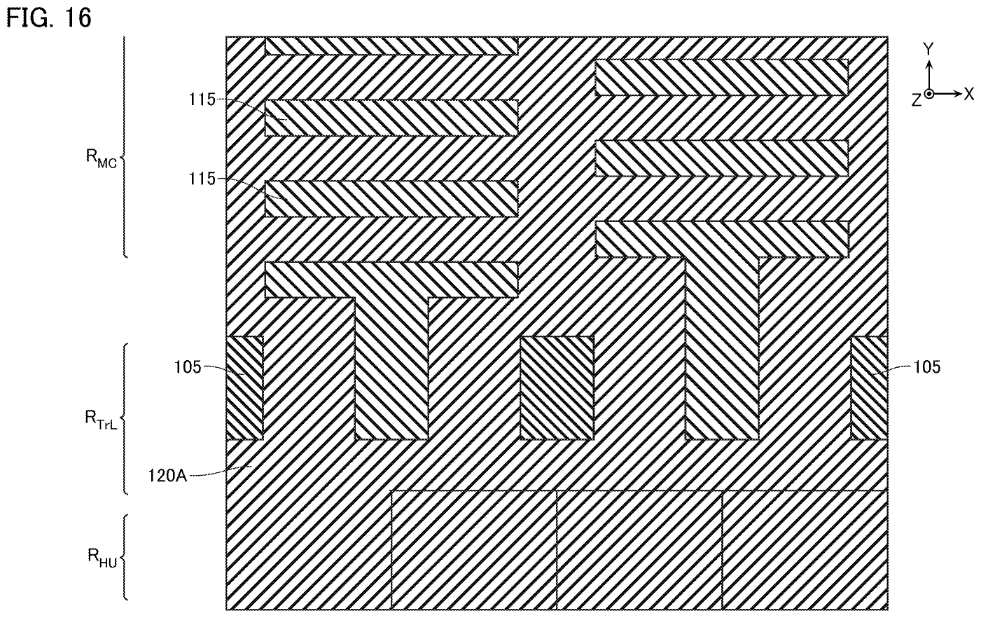

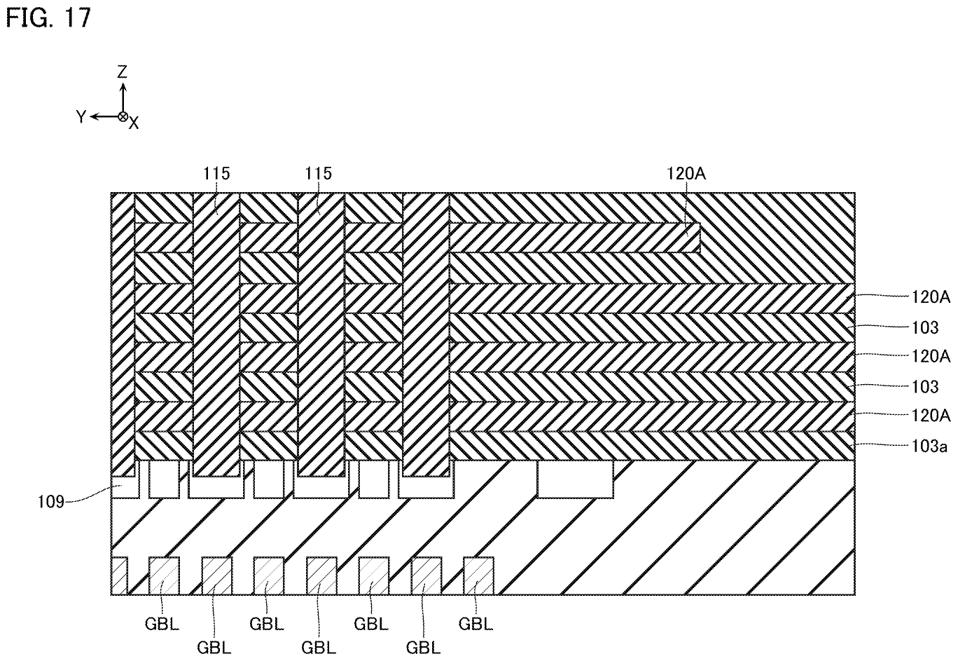

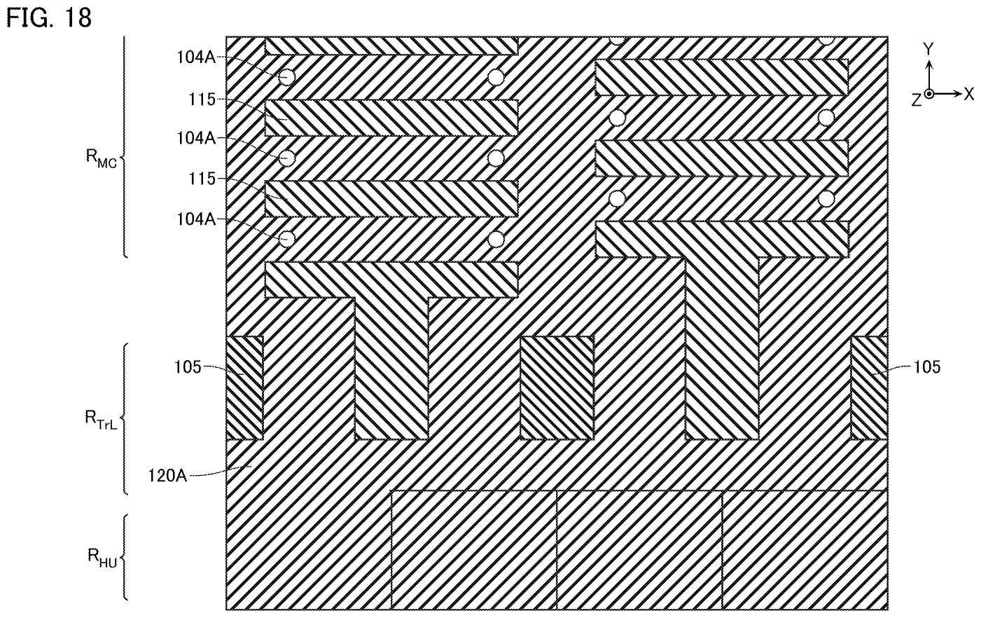

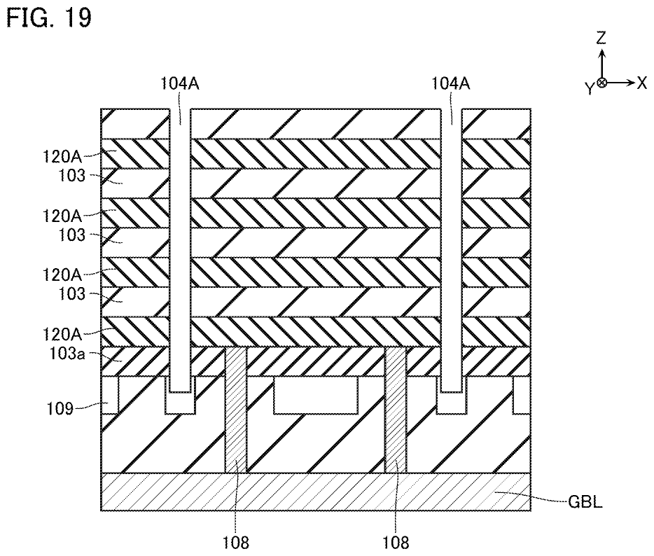

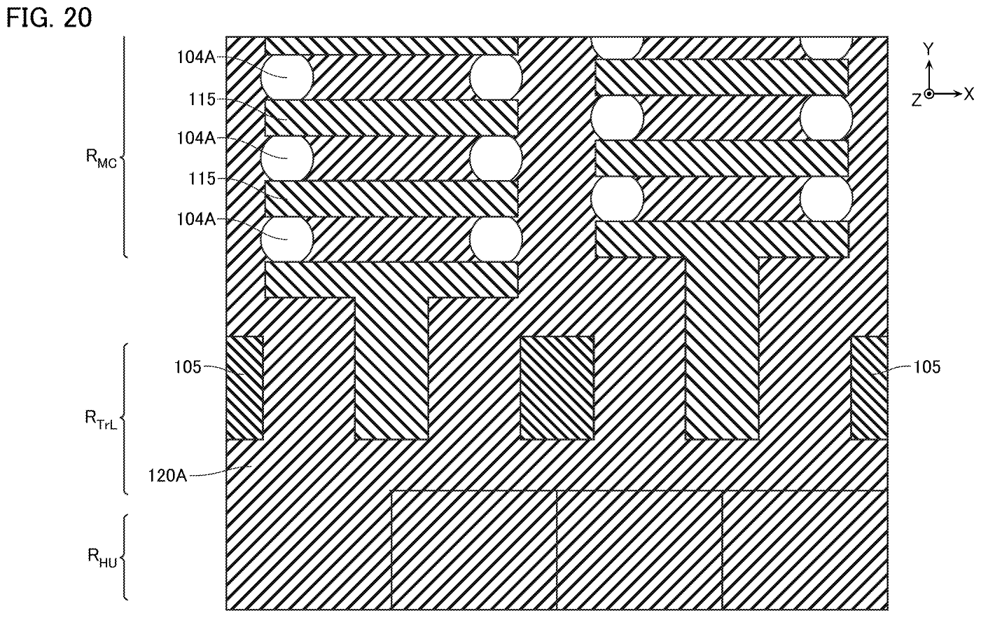

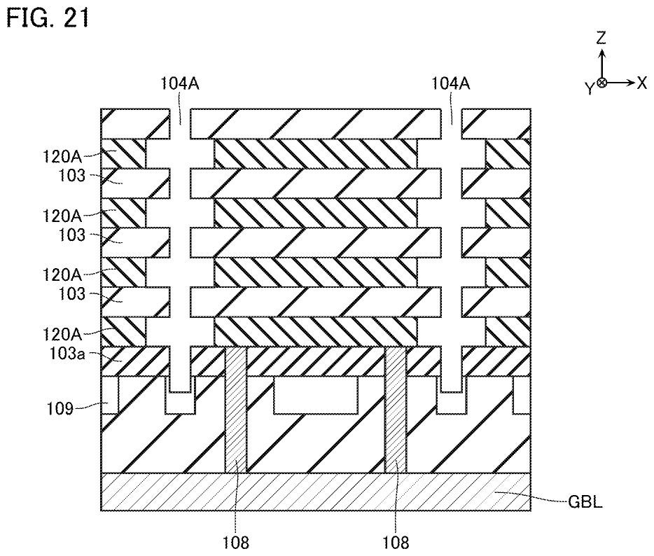

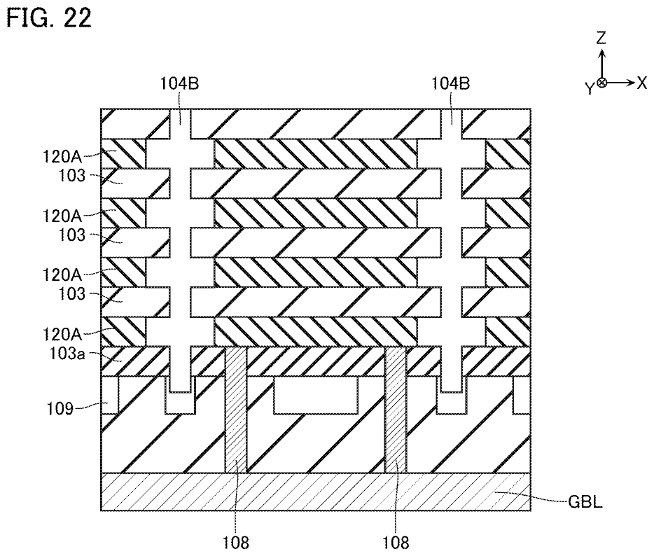

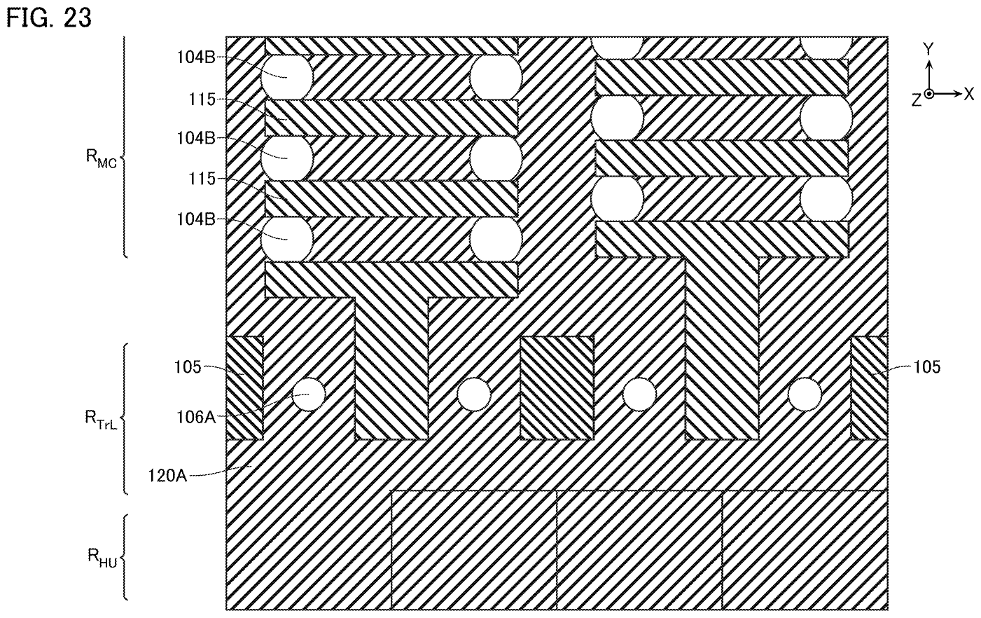

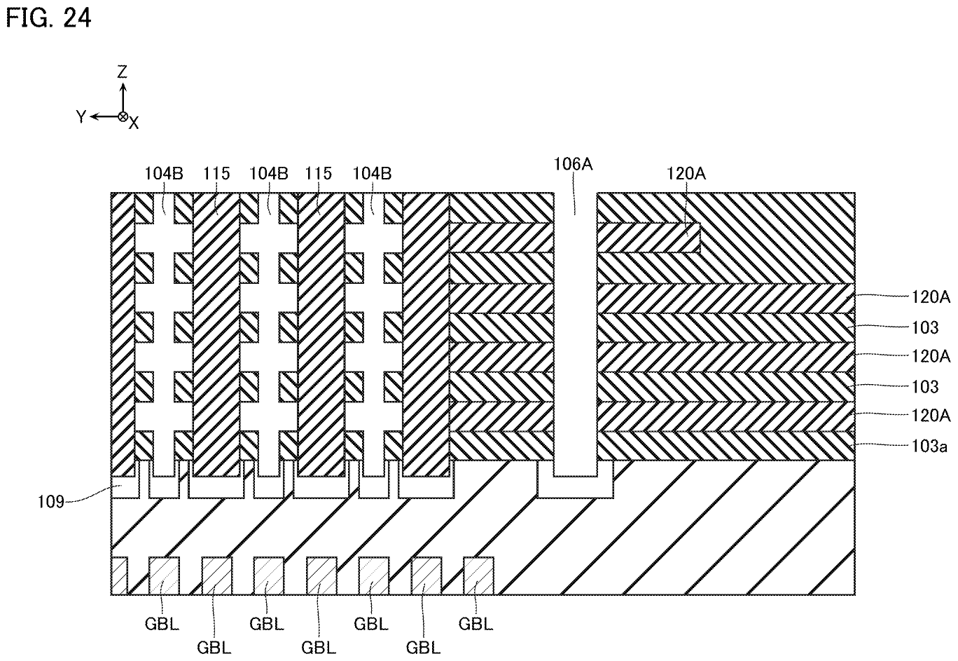

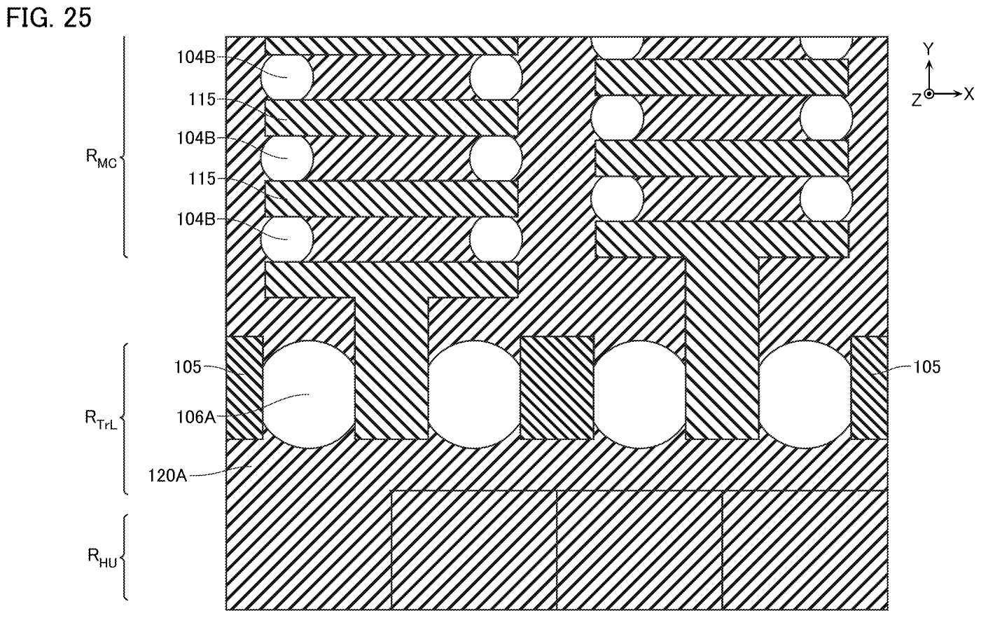

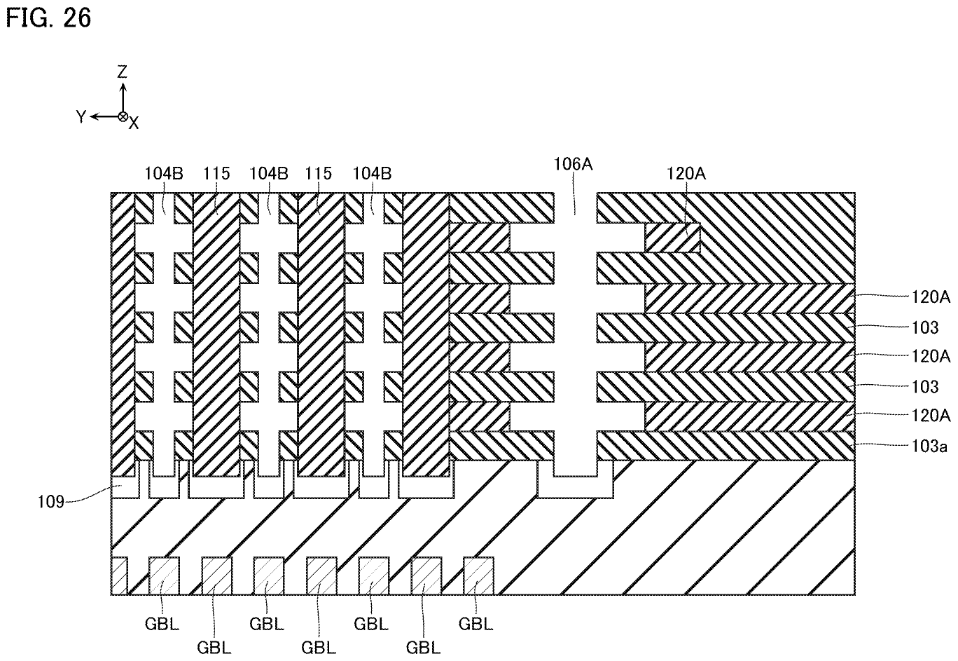

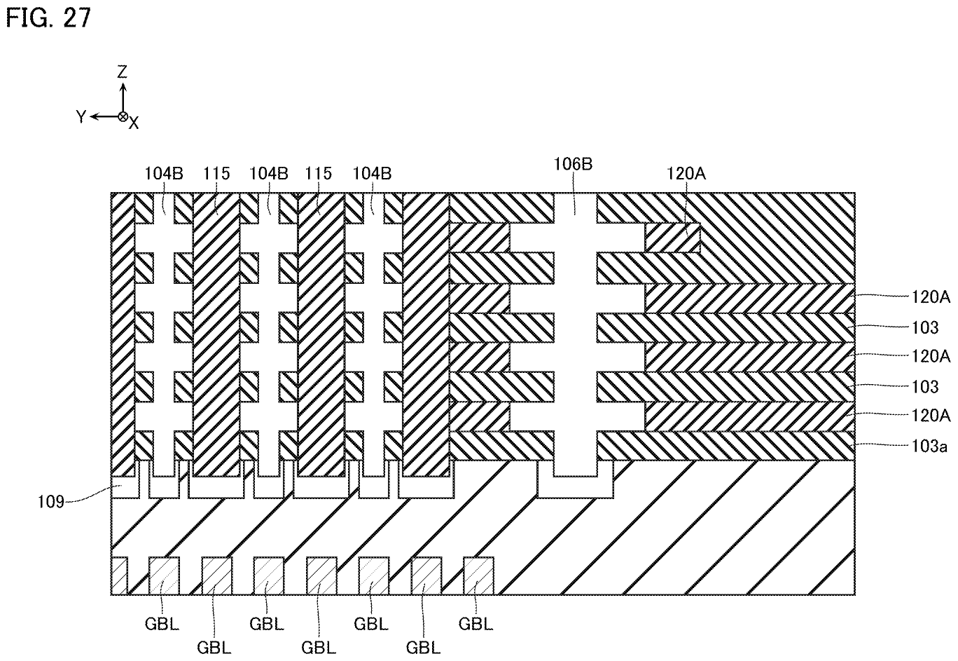

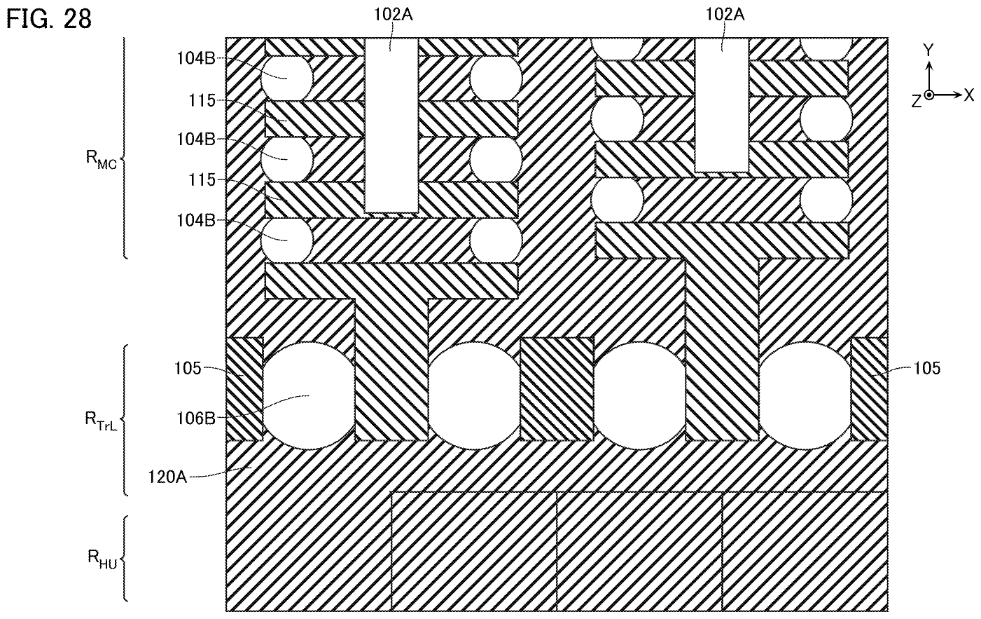

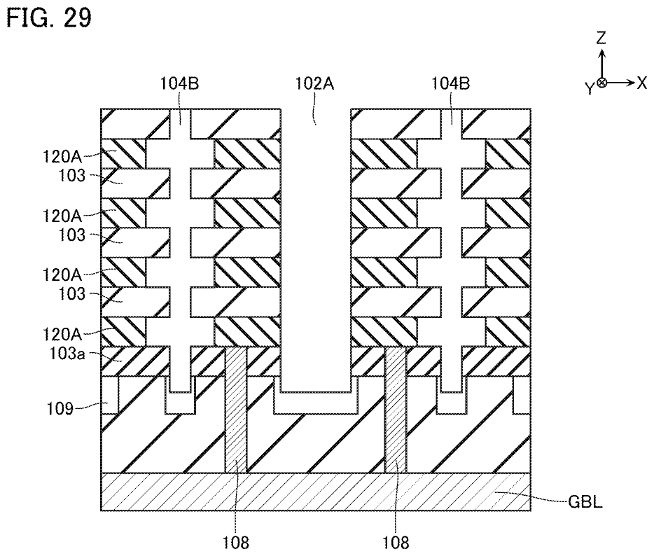

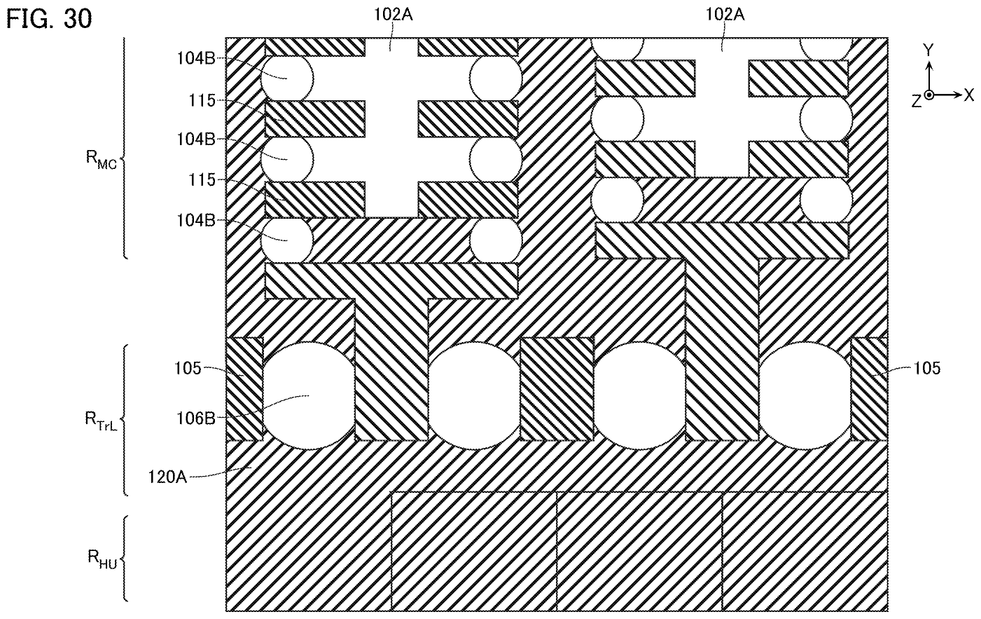

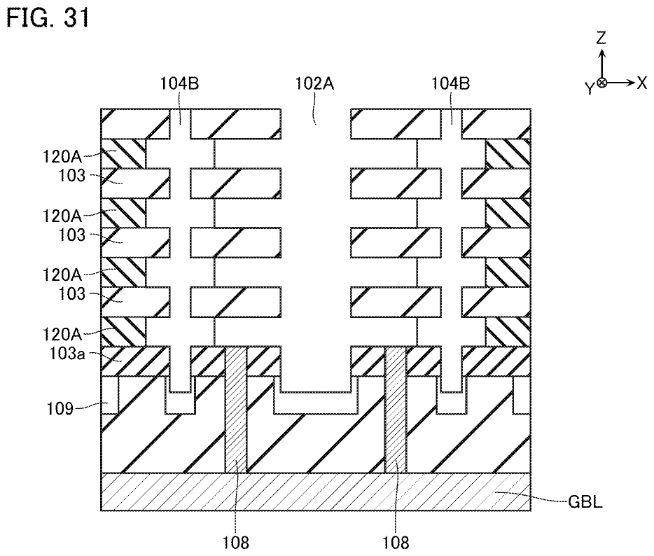

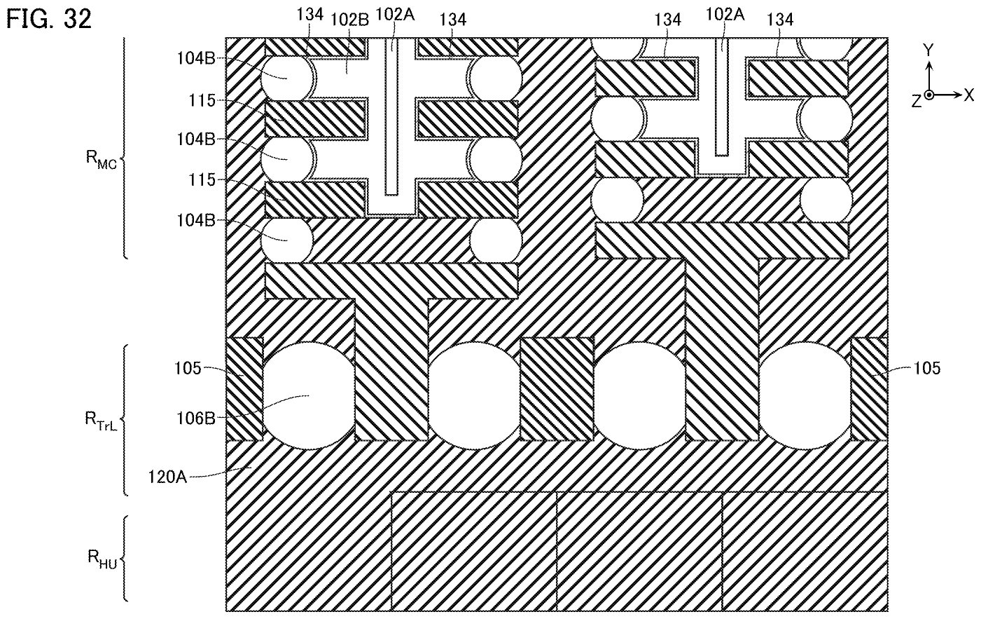

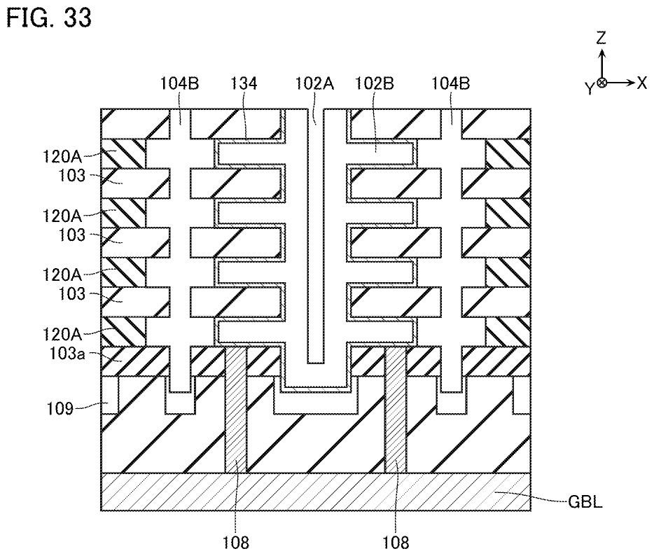

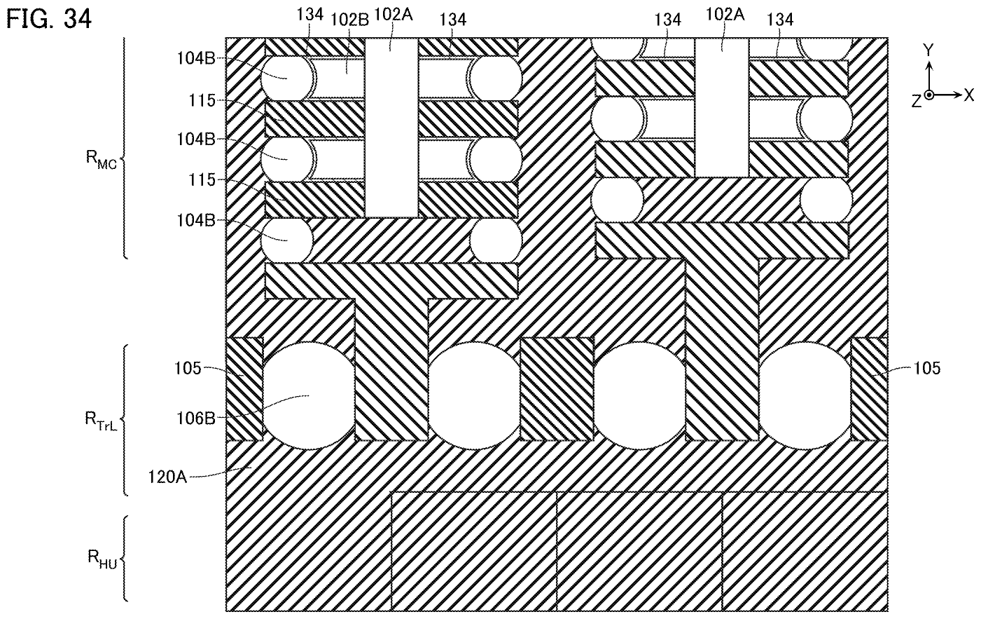

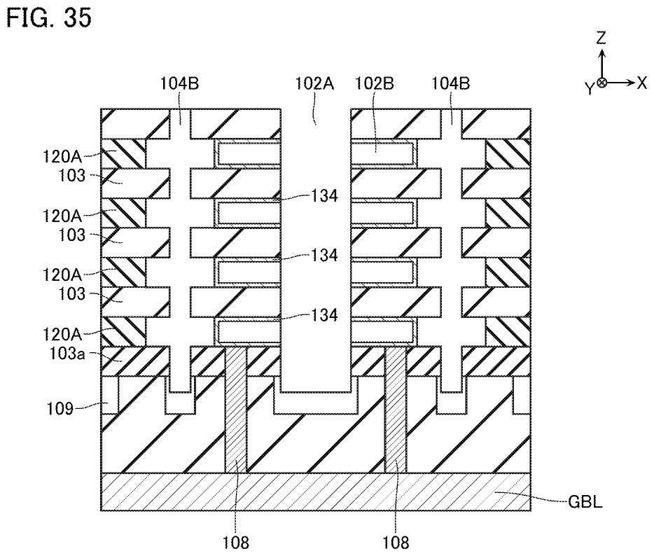

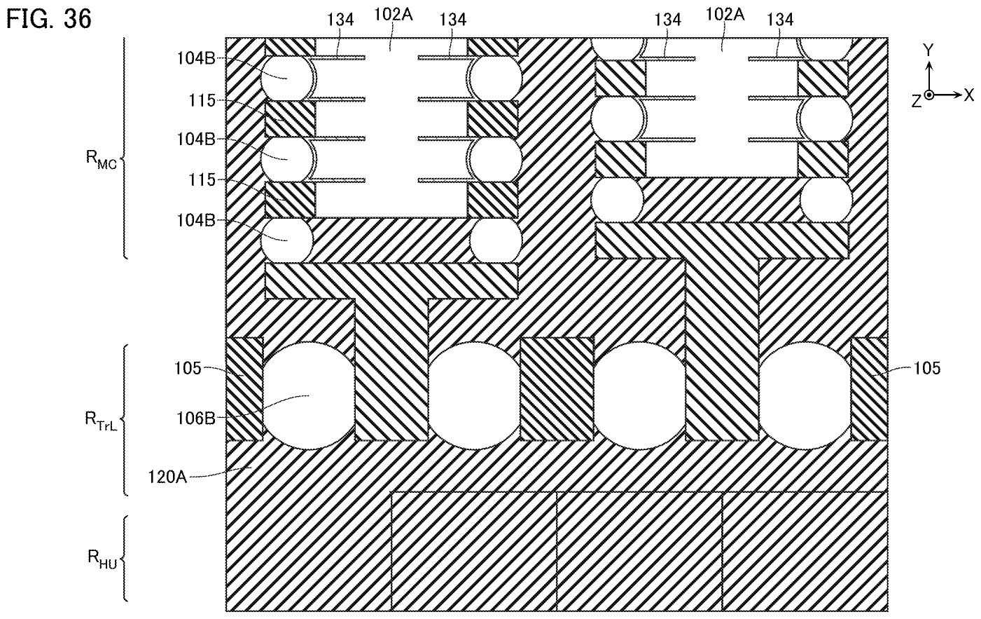

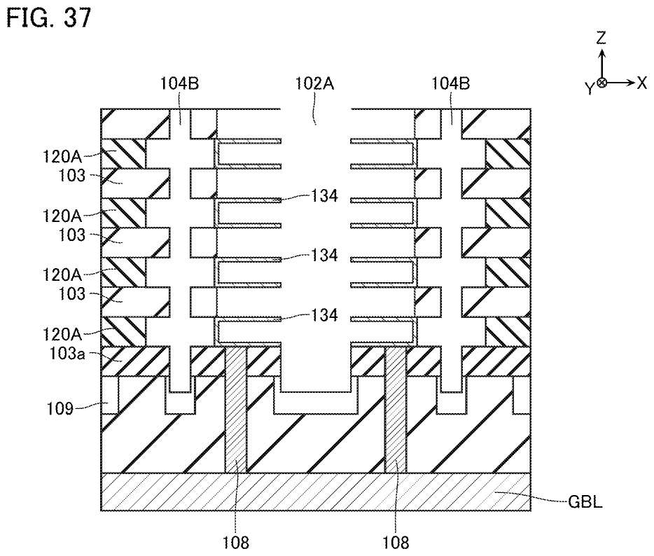

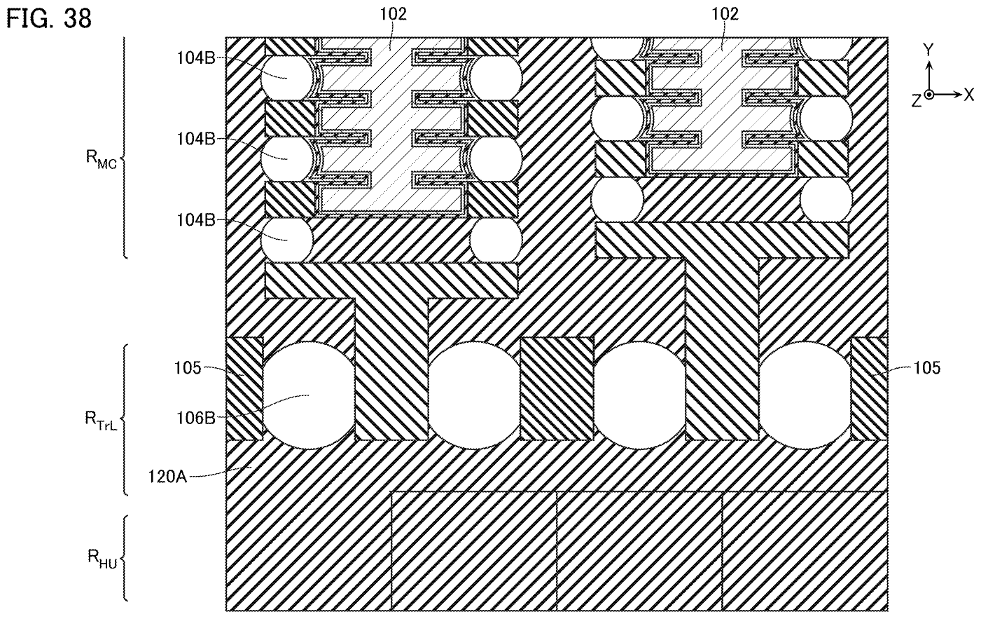

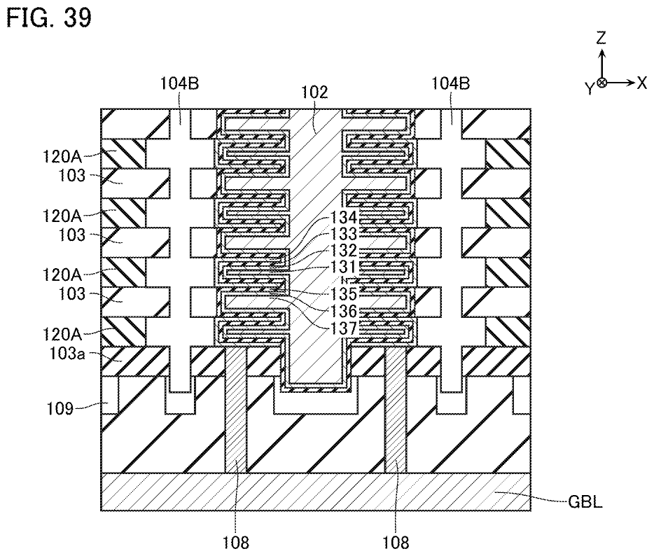

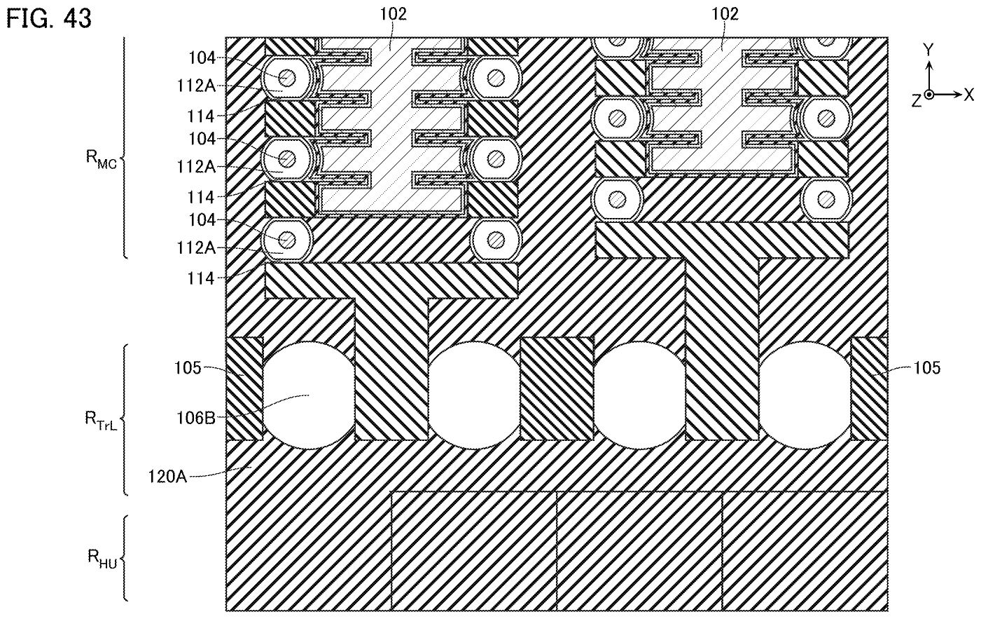

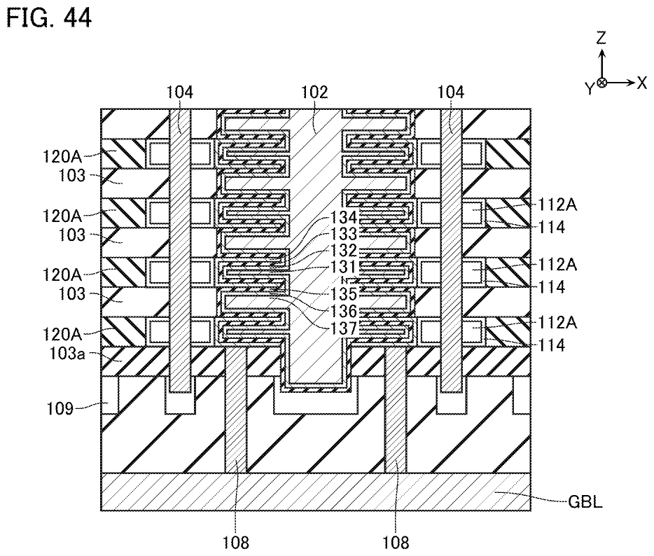

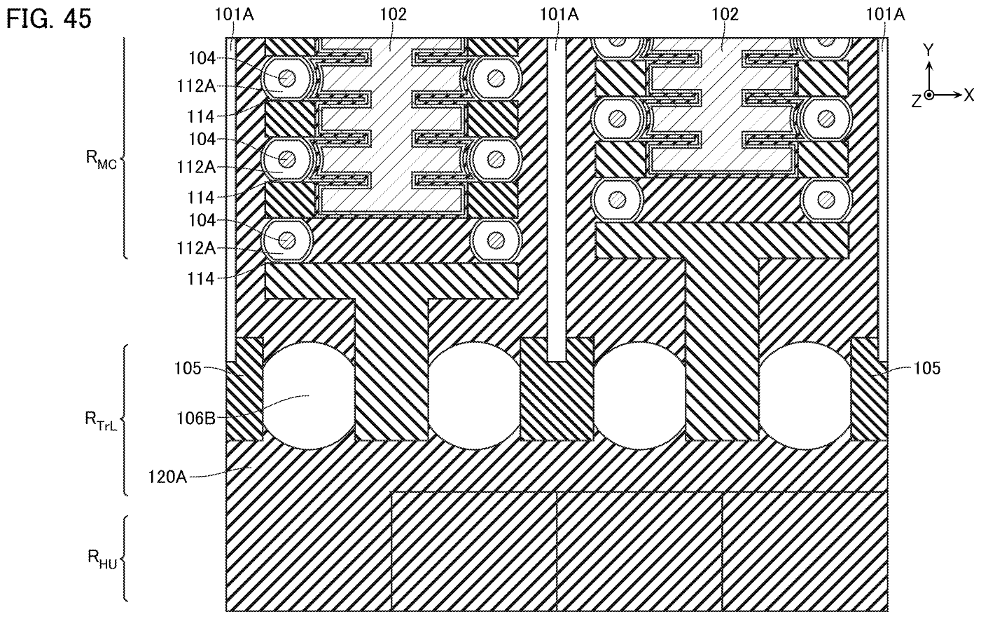

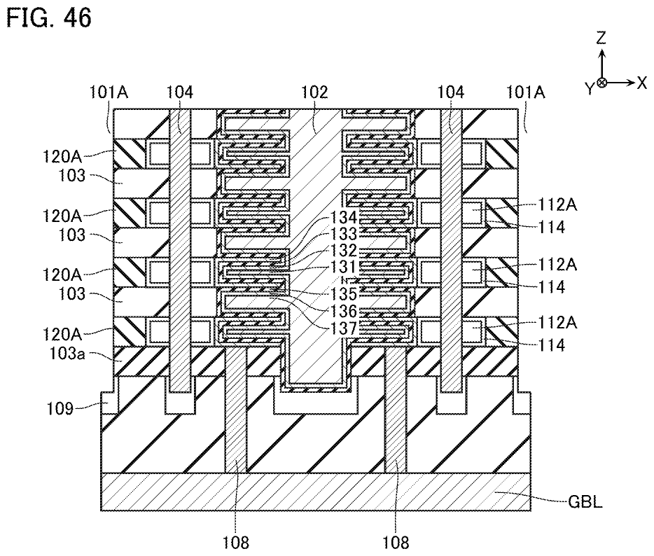

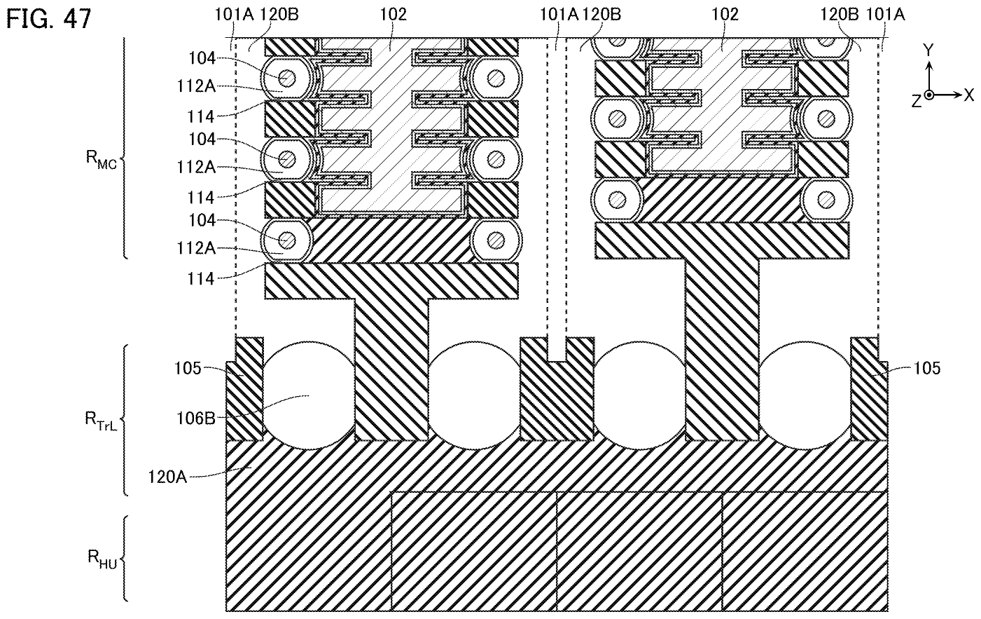

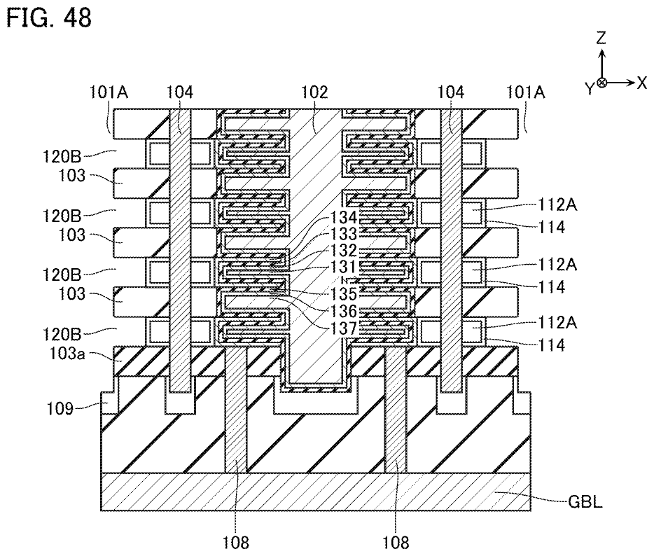

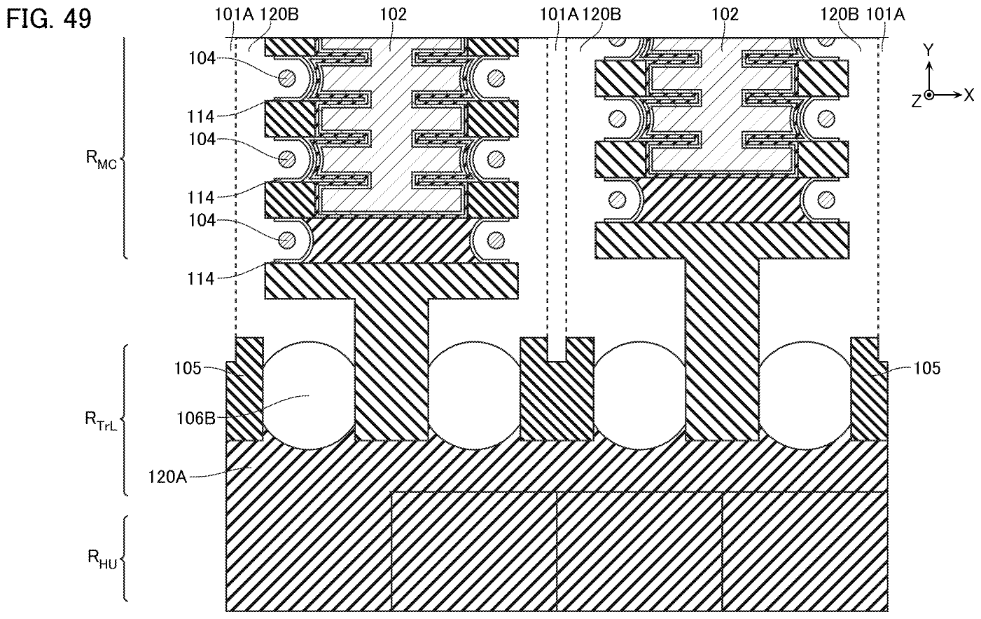

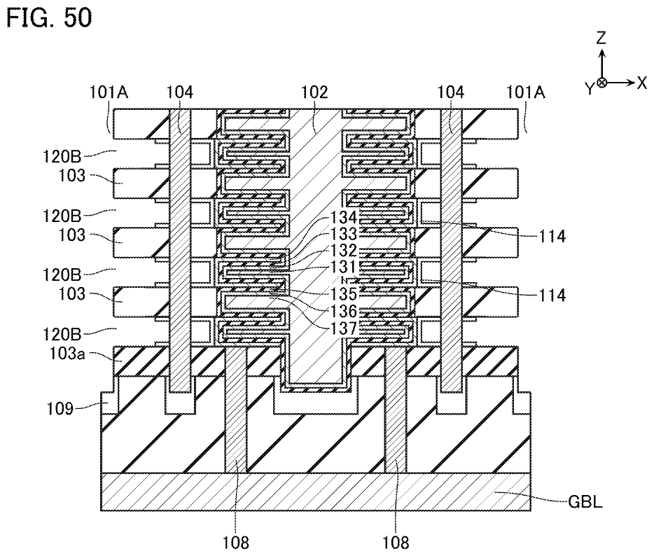

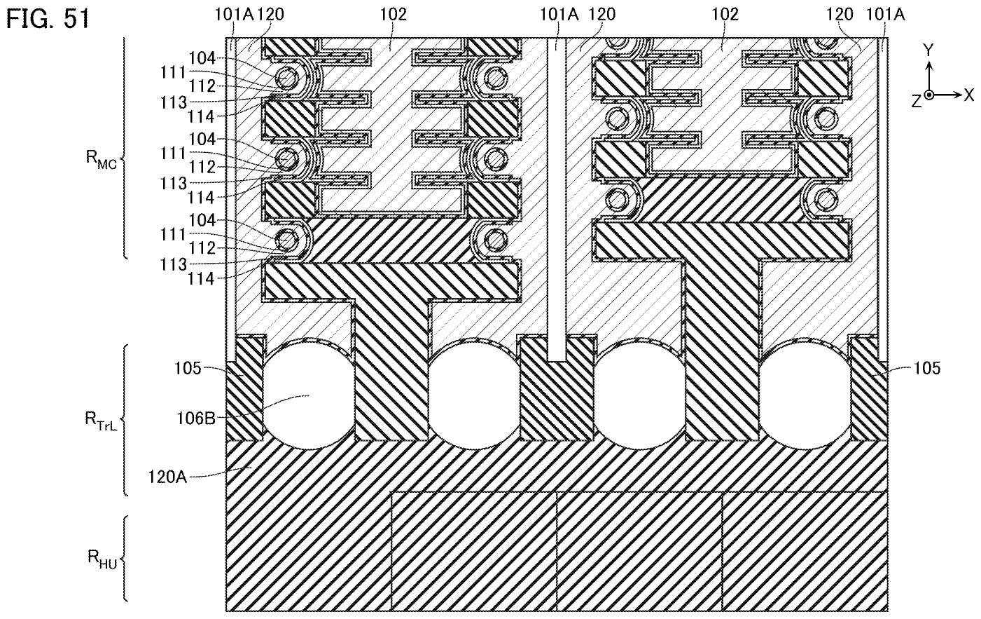

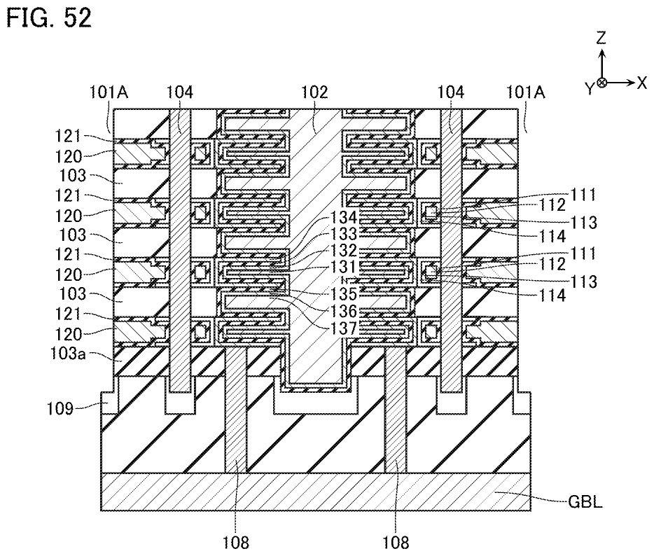

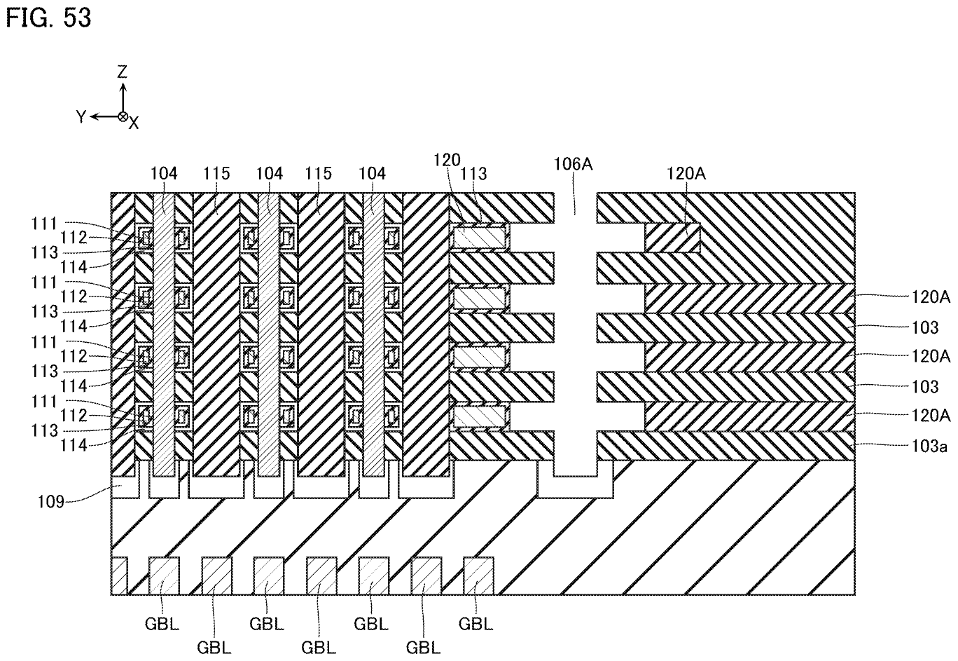

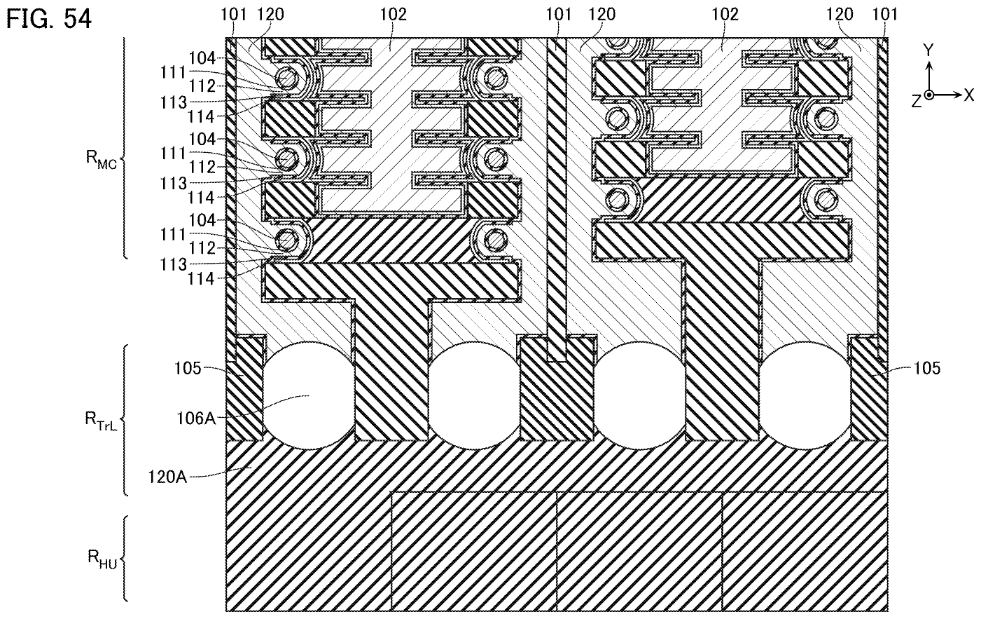

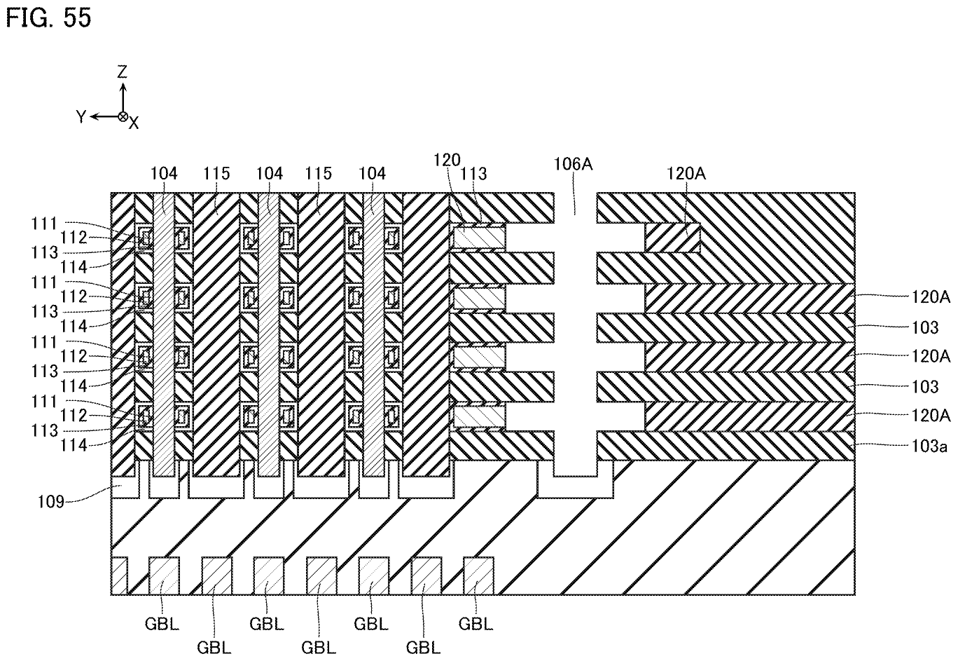

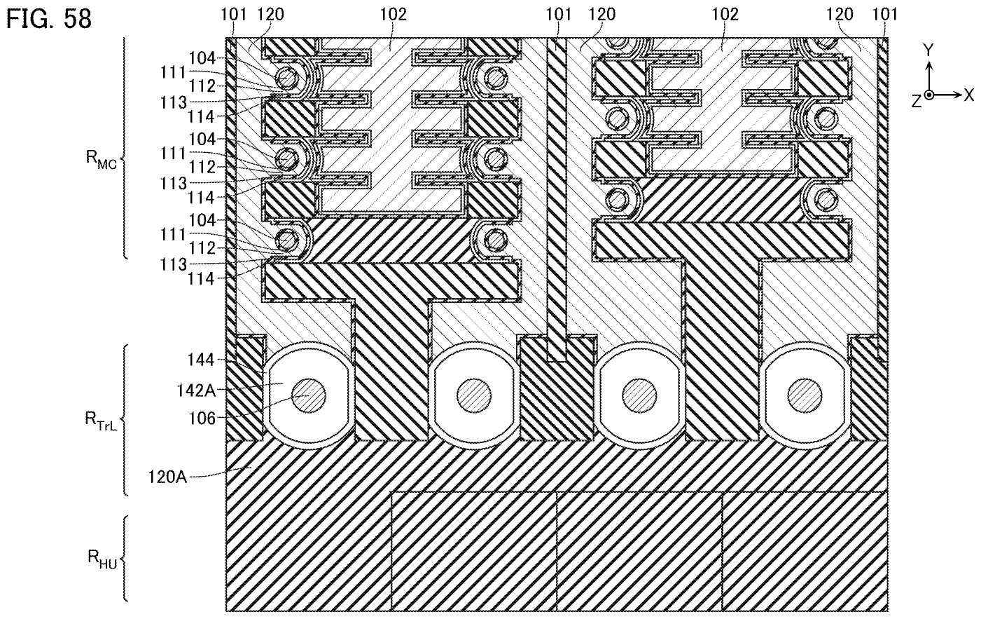

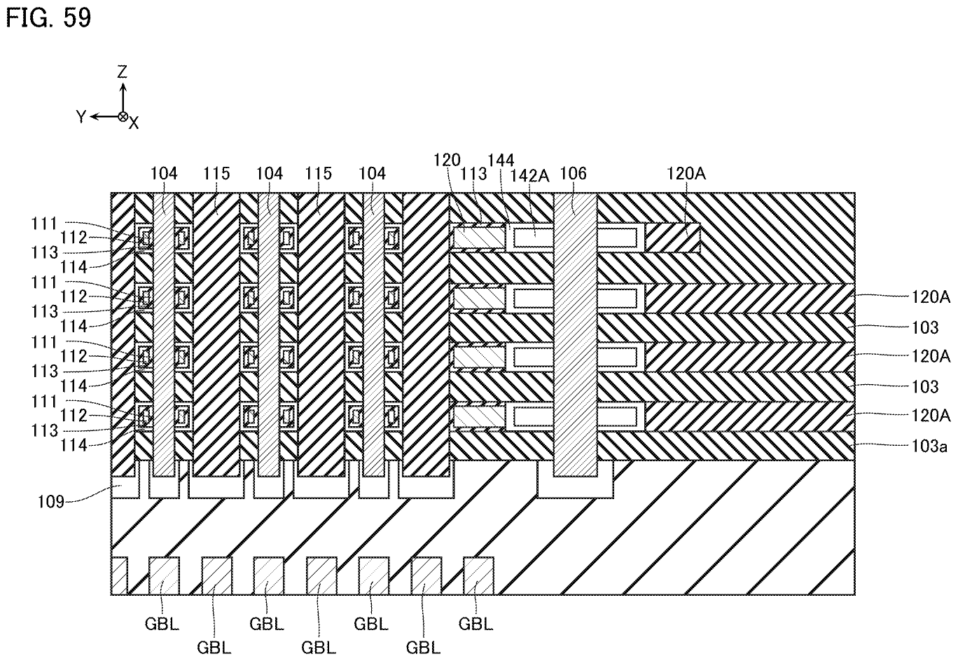

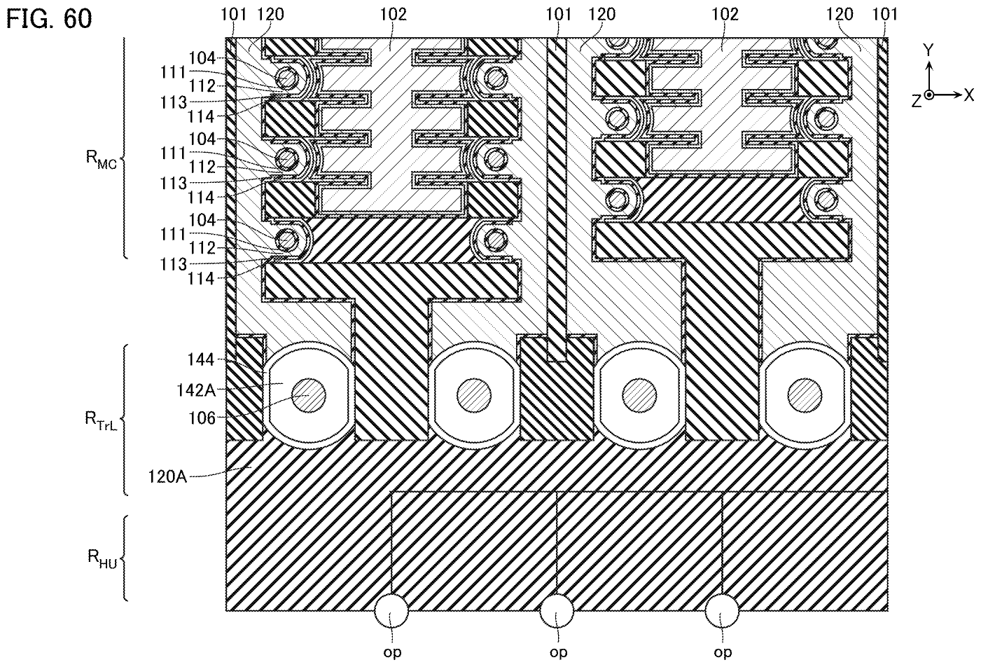

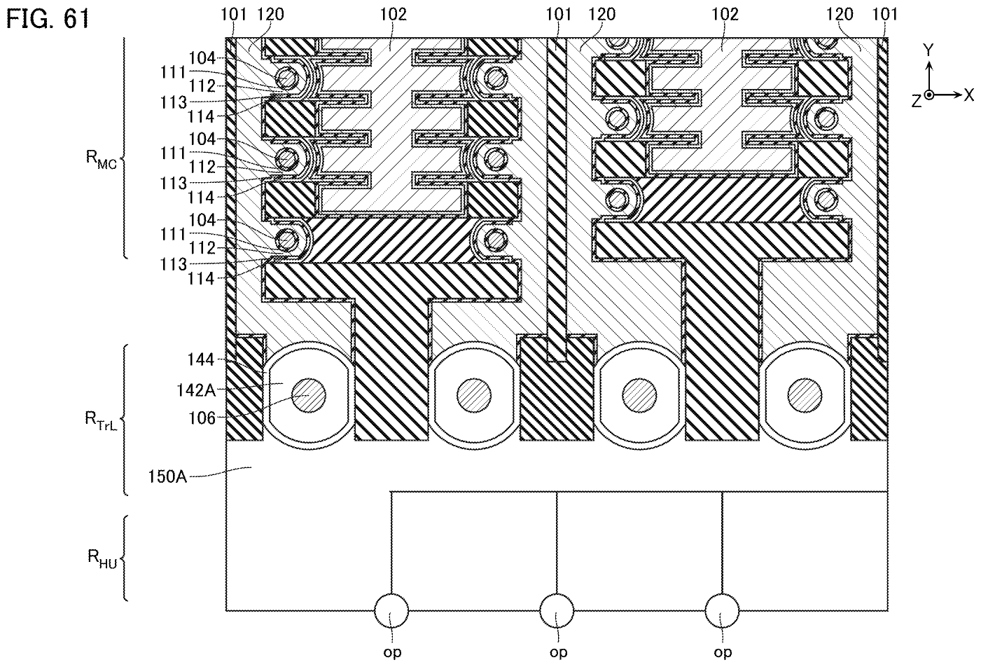

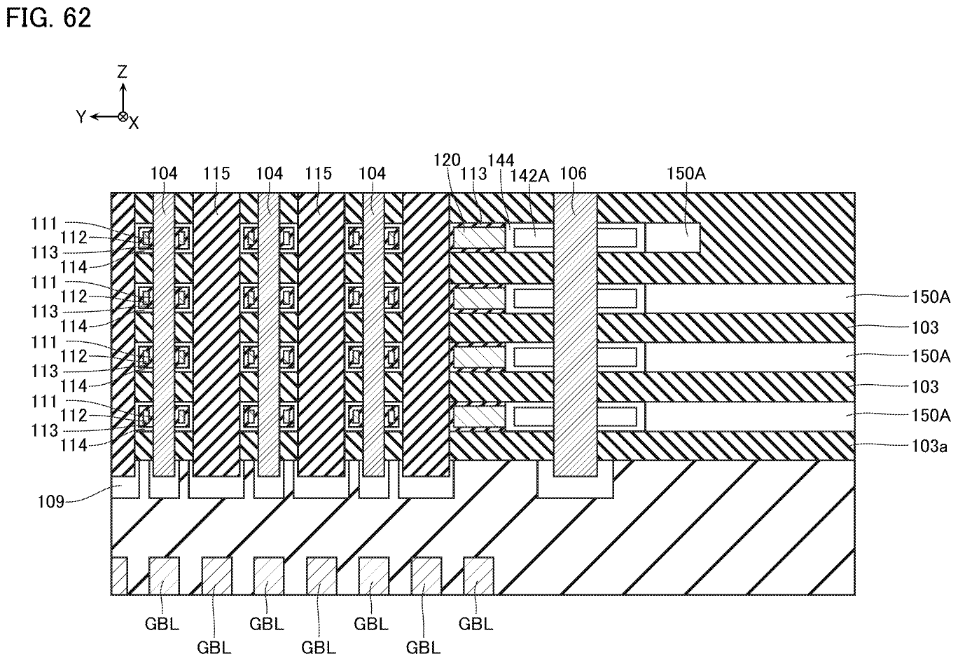

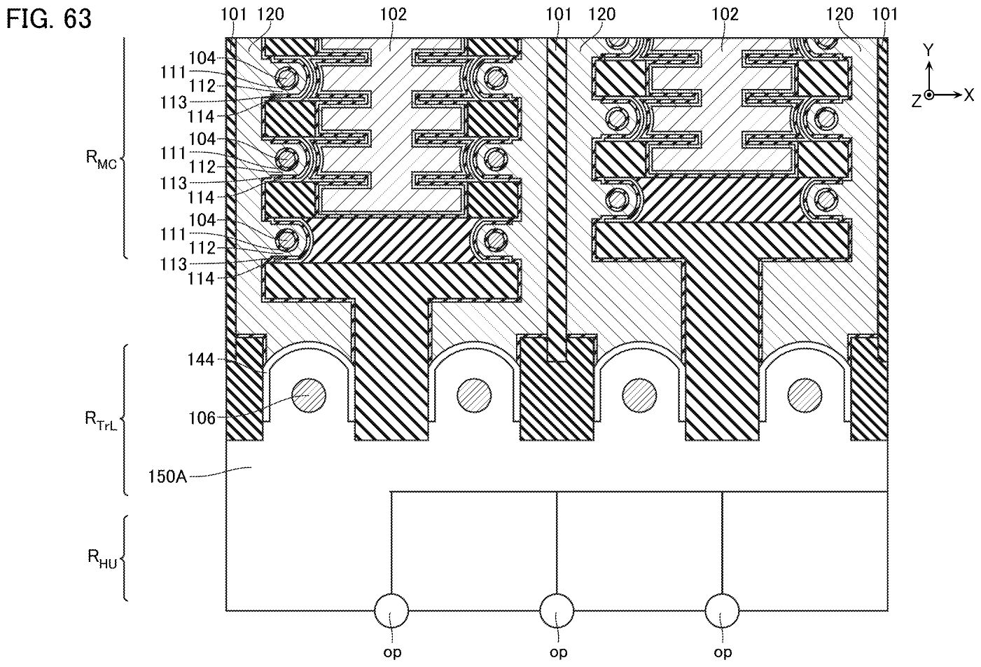

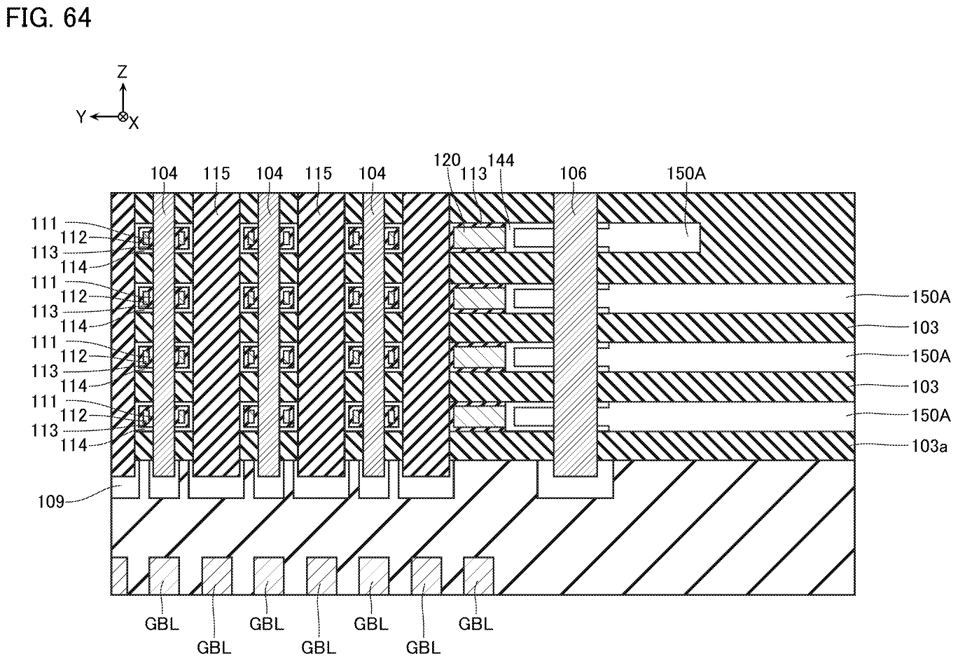

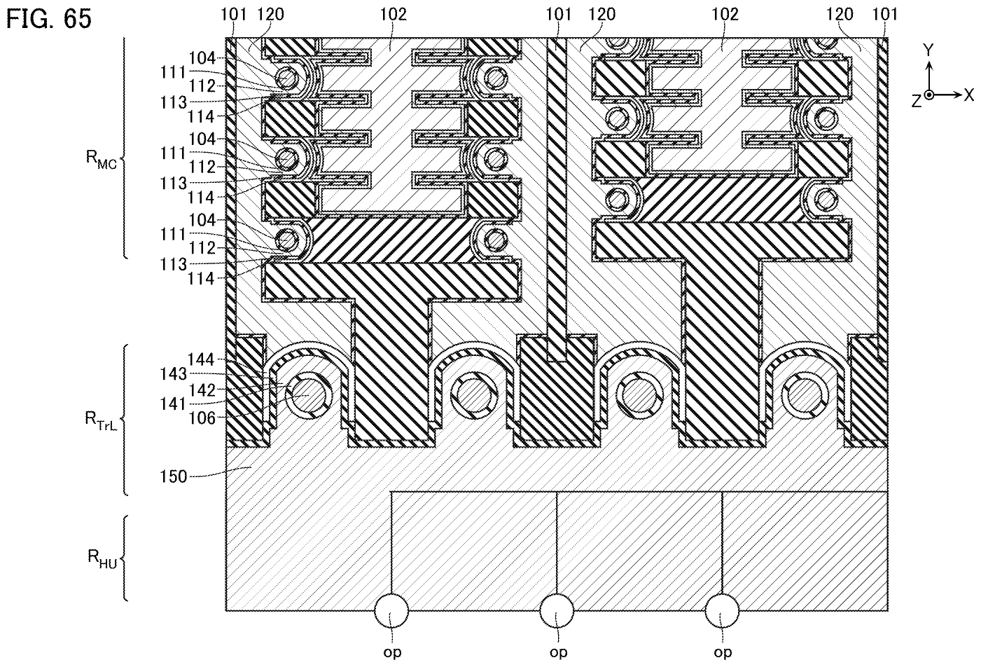

FIG. 12 to FIG. 66 are schematic cross-sectional views for describing the method for manufacturing the semiconductor memory device according to the first embodiment. FIG. 13, FIG. 14, FIG. 16, FIG. 18, FIG. 20, FIG. 23, FIG. 25, FIG. 28, FIG. 30, FIG. 32, FIG. 34, FIG. 36, FIG. 38, FIG. 43, FIG. 45, FIG. 47, FIG. 49, FIG. 51, FIG. 54, FIG. 58, FIG. 60, FIG. 61, FIG. 63, and FIG. 65 each illustrate a cross-sectional surface corresponding to that in FIG. 8. FIG. 12, FIG. 19, FIG. 21, FIG. 22, FIG. 29, FIG. 31, FIG. 33, FIG. 35, FIG. 37, FIG. 39 to FIG. 42, FIG. 44, FIG. 46, FIG. 48, FIG. 50, and FIG. 52 each illustrate a cross-sectional surface corresponding to that in FIG. 9. FIG. 15, FIG. 17, FIG. 24, FIG. 26, FIG. 27, FIG. 53, FIG. 55 to FIG. 57, FIG. 59, FIG. 62, FIG. 64, and FIG. 66 each illustrate a cross-sectional surface corresponding to that in FIG. 10.

For example, as illustrated in FIG. 12, in the manufacturing method, a plurality of the global bit lines GBL, the etching stoppers 109, the insulating layer 103a, the contact electrodes 108, and the like are formed. This process is performed by photolithography, etching, or the like.

Next, for example, as illustrated in FIG. 12, a plurality of the insulating layers 103 and a plurality of sacrifice layers 120A are alternately formed. The sacrifice layer 120A contains silicon nitride (Si₃N₄) or the like. This process is performed by Chemical Vapor Deposition (CVD) or the like.

Next, for example, as illustrated in FIG. 13, in the hook-up region R_{HU}, the plurality of insulating layers 103 and the plurality of sacrifice layers 120A are partially removed to form a staircase-shaped structure.

In this process, for example, a resist to expose a part of the hook-up region R_{HU} is formed on an upper surface of the structure as illustrated in FIG. 12. Next, the sacrifice layer 120A is selectively removed by a method such as Reactive Ion Etching (RIE). Next, the insulating layer 103 is selectively removed by the method such as RIE. Thus, a part of an upper surface of the second sacrifice layer 120A counting from above is exposed.

Next, a part of the resist is removed by a method such as wet etching. Next, the sacrifice layer 120A is selectively removed by the method such as RIE. Next, the insulating layer 103 is selectively removed by the method such as RIE. Thus, upper surfaces of the second and third sacrifice layers 120A counting from above are partially exposed.

In the following, similarly, the removal of a part of the resist, the selective removal of the sacrifice layer 120A, and the selective removal of the insulating layer 103 are repeatedly performed. Accordingly, the upper surfaces of all of the sacrifice layers 120A are partially exposed, thus forming the staircase-shaped structure. After the formation of the staircase-shaped structure, the insulating layer 103 is formed on the uppermost sacrifice layer 120A and the upper surface of the staircase-shaped structure.

Next, for example, as illustrated in FIG. 14 and FIG. 15, openings 115A, 105A are formed at positions corresponding to the insulating layers 115, 105. The openings 115A, 105A extend in the Z-direction as illustrated in FIG. 15, and penetrate the plurality of insulating layers 103, the plurality of sacrifice layers 120A, and the insulating layer 103a arranged in the Z-direction, thus exposing the upper surfaces of the etching stoppers 109. This process is performed by RIE or the like.

Next, for example, as illustrated in FIG. 16 and FIG. 17, the insulating layers 115, 105 are formed. This process is performed by CVD or the like.

Next, for example, as illustrated in FIG. 18 and FIG. 19, openings 104A are formed at positions corresponding to the conductive layers 104. The openings 104A extend in the Z-direction as illustrated in FIG. 19, and penetrate the plurality of insulating layers 103, the plurality of sacrifice layers 120A, and the insulating layer 103a arranged in the Z-direction, thus exposing the upper surfaces of the etching stoppers 109. This process is performed by RIE or the like.

Next, for example, as illustrated in FIG. 20 and FIG. 21, parts of the sacrifice layers 120A are selectively removed via the openings 104A. In this process, side surfaces of the insulating layers 115 in the Y-direction are exposed to insides of the openings 104A, thereby separating the sacrifice layers 120A in the X-direction. This process is performed by wet etching or the like.

Next, for example, as illustrated in FIG. 22, sacrifice layers 104B are formed inside the openings 104A. The sacrifice layer 104B contains silicon (Si) or the like. This process is performed by CVD or the like.

Next, for example, as illustrated in FIG. 23 and FIG. 24, openings 106A are formed at positions corresponding to the conductive layers 106. The openings 106A extend in the Z-direction as illustrated in FIG. 24, and penetrate the plurality of insulating layers 103, the plurality of sacrifice layers 120A, and the insulating layer 103a arranged in the Z-direction, thus exposing the upper surfaces of the etching stoppers 109. This process is performed by RIE or the like.

Next, for example, as illustrated in FIG. 25 and FIG. 26, parts of the sacrifice layers 120A are selectively removed via the openings 106A. In this process, side surfaces in the X-direction of the insulating layers 105 are exposed to insides of the openings 106A, thereby separating the sacrifice layers 120A in the Y-direction. This process is performed by wet etching or the like.

Next, for example, as illustrated in FIG. 27, sacrifice layers 106B are formed inside the openings 106A. The sacrifice layer 106B contains silicon (Si) or the like. This process is performed by CVD or the like.

Next, for example, as illustrated in FIG. 28 and FIG. 29, openings 102A are formed at positions corresponding to the conductive layers 102. The openings 102A extend in the Z-direction as illustrated in FIG. 29, and penetrate the plurality of insulating layers 103, the plurality of sacrifice layers 120A, and the insulating layer 103a arranged in the Z-direction, thus separating these configurations in the X-direction and exposing the upper surfaces of the etching stoppers 109. This process is performed by RIE or the like.

Next, for example, as illustrated in FIG. 30 and FIG. 31, parts of the sacrifice layers 120A are selectively removed via the openings 102A. In this process, side surfaces in the X-direction of the sacrifice layers 104B are exposed to insides of the openings 102A. This process is performed by wet etching or the like.

Next, for example, as illustrated in FIG. 32 and FIG. 33, the conductive layers 134 are formed on side surfaces in the X-direction of the sacrifice layers 104B, side surfaces in the X-direction and the Y-direction of the insulating layers 115, and upper surfaces, lower surfaces, and side surfaces in the X-direction of the insulating layers 103 (FIG. 33) via the openings 102A. Sacrifice layers 102B are formed inside the openings 102A. The sacrifice layer 102B contains silicon (Si) or the like. In this process, for example, as illustrated in FIG. 33, a region between the two insulating layers 103 mutually adjacent in the Z-direction is filled with the sacrifice layer 102B. Meanwhile, a region between the two insulating layers 103 mutually adjacent in the X-direction is not filled with the sacrifice layer 102B. This process is performed by, for example, Atomic Layer Deposition (ALD) and CVD.

Next, for example, as illustrated in FIG. 34 and FIG. 35, the sacrifice layers 102B and the conductive layers 134 are partially removed via the openings 102A. In this process, for example, parts of the sacrifice layers 102B are removed to expose the parts of the conductive layers 134 disposed on the side surfaces in the X-direction of the insulating layers 115 (FIG. 32) and the insulating layers 103 (FIG. 33), thus removing these parts. This process is performed by wet etching or the like.

Next, for example, as illustrated in FIG. 36 and FIG. 37, the sacrifice layers 102B, parts of the insulating layers 115 (FIG. 34), and parts of the insulating layers 103 (FIG. 35) are removed via the openings 102A. In this process, the sacrifice layers 102B are completely removed.

The insulating layers 115 (FIG. 34) and the insulating layers 103 (FIG. 35) are removed in a range where the sacrifice layers 104B are not exposed to the openings 102A. This process is performed by wet etching or the like.

Next, for example, as illustrated in FIG. 38 and FIG. 39, the insulating layers 133, 135, the conductive layers 132, 136, and the conductive layers 131, 137, 102 are formed on upper surfaces, lower surfaces, side surfaces in the X-direction, side surfaces in the Y-direction of the conductive layers 134 via the openings 102A. This process is performed by CVD or the like.

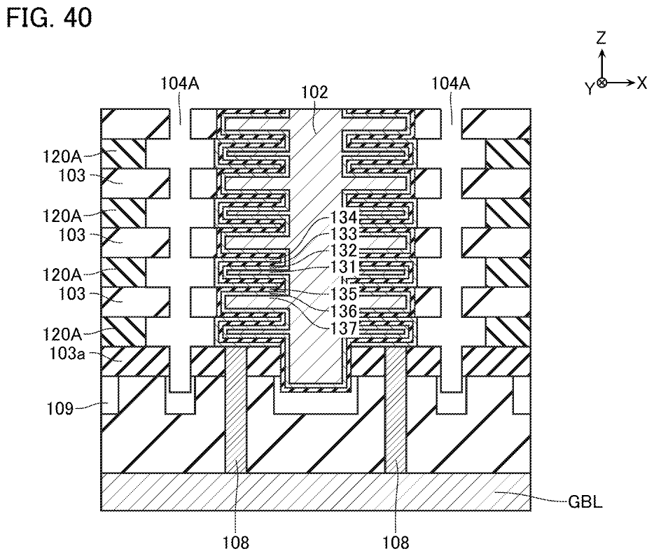

Next, for example, as illustrated in FIG. 40, the sacrifice layers 104B are removed. This process is performed by wet etching or the like.

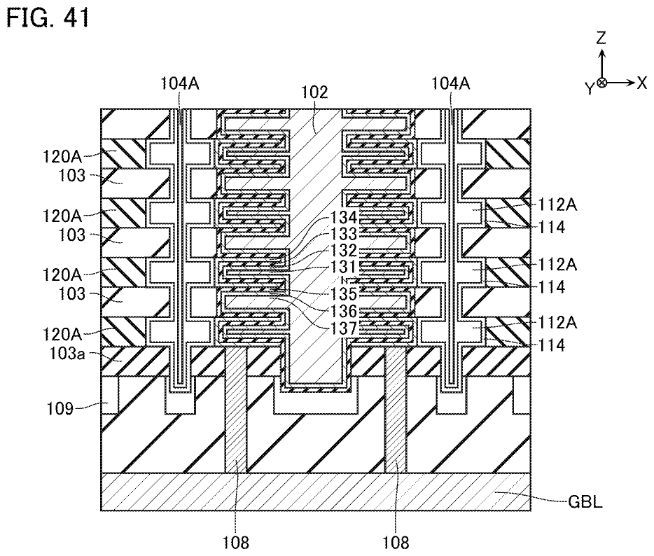

Next, for example, as illustrated in FIG. 41, the semiconductor layers 114 are formed on side surfaces in the X-direction of the sacrifice layers 120A and the conductive layers 134, the side surfaces in the Y-direction of the insulating layers 115, and upper surfaces and lower surfaces of the insulating layers 103 via the openings 104A. Sacrifice layers 112A are each formed in a region between the two insulating layers 103 mutually adjacent in the Z-direction. In this process, for example, as illustrated in FIG. 41, the regions between two insulating layers 103 mutually adjacent in the Z-direction are filled with the sacrifice layers 112A. Meanwhile, the openings 104A are not filled with the sacrifice layers 112A. This process is performed by, for example, ALD and CVD.

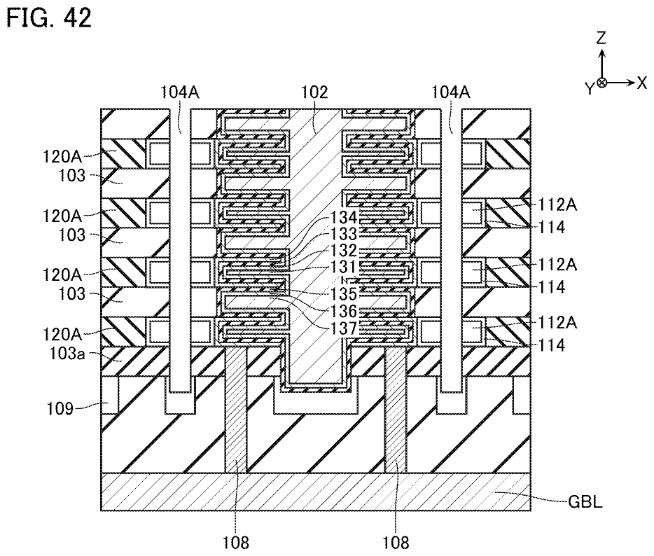

Next, for example, as illustrated in FIG. 42, the sacrifice layers 112A and the semiconductor layers 114 are partially removed via the openings 104A. In this process, for example, parts of the sacrifice layers 112A are removed to expose parts of the semiconductor layers 114 disposed on inner peripheral surfaces of the insulating layers 103, and these parts are removed. This process is performed by wet etching or the like.

Next, for example, as illustrated in FIG. 43 and FIG. 44, the conductive layers 104 are formed inside the openings 104A. This process is performed by, for example, ALD and CVD.

Next, for example, as illustrated in FIG. 45 and FIG. 46, openings 101A are formed at positions corresponding to the insulating layers 101. The openings 101A extend in the Z-direction as illustrated in FIG. 46, and penetrate the plurality of insulating layers 103, the plurality of sacrifice layers 120A, and the insulating layer 103a arranged in the Z-direction to separate these configurations in the X-direction, thus exposing upper surfaces of the etching stoppers 109. This process is performed by RIE or the like.

Next, for example, as illustrated in FIG. 47 and FIG. 48, the sacrifice layers 120A are removed via the openings 101A. This process is performed by wet etching or the like. In the drawing, openings formed at the portions at which the sacrifice layers 120A were disposed are illustrated as openings 120B.

Next, for example, as illustrated in FIG. 49 and FIG. 50, parts of the semiconductor layers 114 are removed via the openings 101A, 120B, thus exposing parts of the sacrifice layers 112A. The sacrifice layers 112A are removed via the openings 101A, 120B, thus exposing the outer peripheral surfaces of the conductive layers 104. This process is performed by wet etching or the like.

Next, for example, as illustrated in FIG. 51 and FIG. 52, the insulating layers 111, 113, 121 are formed, and the conductive layers 112, 120 are formed inside the openings 120B. In this process, for example, the insulating layers and the conductive layers are formed in the openings 101A, 120B by CVD or the like. At this time, the openings 120B are filled with the conductive layers. Meanwhile, the openings 101A are not filled with the conductive layers. Next, for example, in these insulating layers and conductive layers, the parts disposed on the inner peripheral surfaces of the insulating layers 103 are removed by wet etching or the like. Then, the insulating layers 101 are formed inside the openings 101A.

Next, for example, as illustrated in FIG. 53, the sacrifice layers 106B are removed. This process is performed by wet etching or the like.

Next, for example, as illustrated in FIG. 54 and FIG. 55, the insulating layers 113 are partially removed via the openings 106A, thus exposing parts of the conductive layers 120. This process is performed by wet etching or the like.

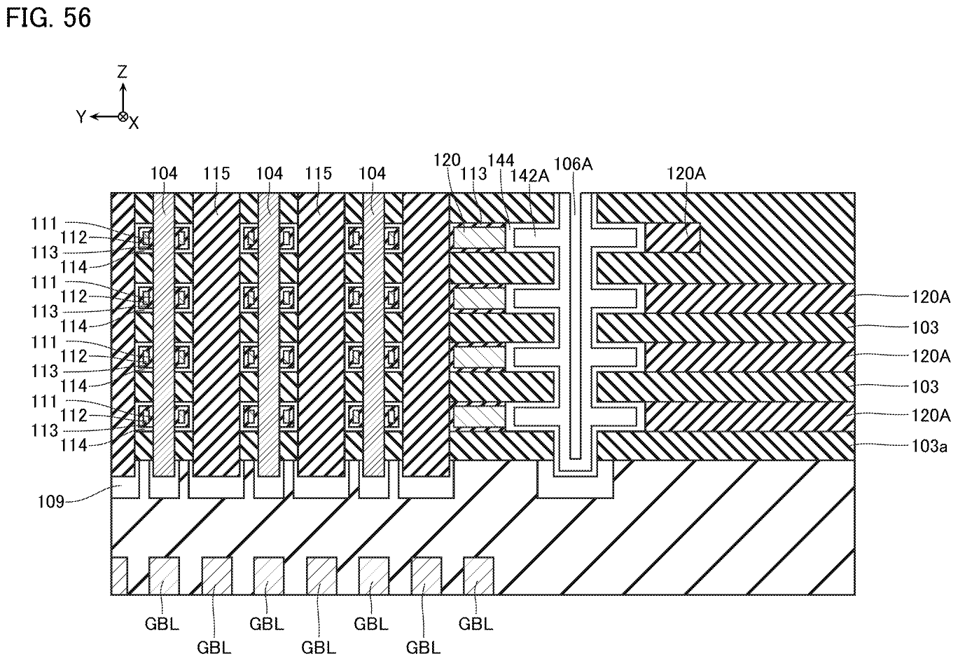

Next, for example, as illustrated in FIG. 56, the semiconductor layers 144 are formed on side surfaces in the Y-direction of the sacrifice layers 120A and the conductive layers 120, side surfaces in the X-direction of the insulating layers 105 and the insulating layers 115, and upper surfaces and lower surfaces of the insulating layers 103 via the openings 106A. Sacrifice layers 142A are each formed in a region between two insulating layers 103 mutually adjacent in the Z-direction. In this process, regions between two insulating layers 103 mutually adjacent in the Z-direction are filled with the sacrifice layers 142A. Meanwhile, the openings 106A are not filled with the sacrifice layers 142A. This process is performed by, for example, ALD and CVD.

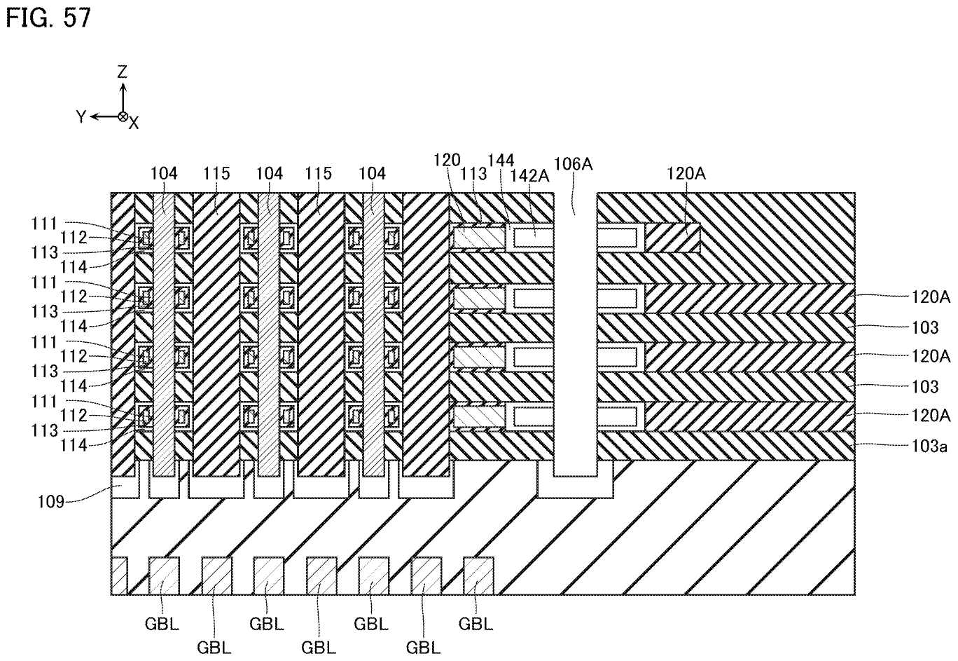

Next, for example, as illustrated in FIG. 57, the sacrifice layers 142A and the semiconductor layers 144 are partially removed via the openings 106A. In this process, for example, the sacrifice layers 142A are partially removed to expose the parts of the semiconductor layers 144 disposed on the inner peripheral surfaces of the insulating layers 103, and these parts are removed. This process is performed by wet etching or the like.

Next, for example, as illustrated in FIG. 58 and FIG. 59, the conductive layers 106 are formed inside the openings 106A. This process is performed by, for example, ALD and CVD.

Next, for example, as illustrated in FIG. 60, a plurality of openings op arranged in the X-direction are formed in the hook-up region R_{HU}. The openings op extend in the Z-direction, and penetrate the plurality of insulating layers 103, the plurality of sacrifice layers 120A, and the insulating layer 103a arranged in the Z-direction, thus exposing the upper surfaces of the etching stoppers 109. This process is performed by RIE or the like.

Next, for example, as illustrated in FIG. 61 and FIG. 62, the sacrifice layers 120A are removed via the openings op. This process is performed by wet etching or the like. In the drawing, openings formed at the portions at which the sacrifice layers 120A were disposed are illustrated as openings 150A.

Next, for example, as illustrated in FIG. 63 and FIG. 64, parts of the semiconductor layers 144 are removed via the openings op, 150A to expose parts of the sacrifice layers 142A. The sacrifice layers 142A are removed via the openings op, 150A to expose the outer peripheral surfaces of the conductive layers 106. This process is performed by wet etching or the like.

Next, for example, as illustrated in FIG. 65 and FIG. 66, the insulating layers 141, 143, 151 are formed and the conductive layers 142, 150 are formed in the openings 150A. In this process, for example, the insulating layers and the conductive layers are formed in the openings op, 150A by CVD or the like. At this time, the openings 150A are filled with the conductive layers. Meanwhile, the openings op are not filled with the conductive layers. Next, for example, in these insulating layers and conductive layers, the parts disposed on the inner peripheral surfaces of the insulating layers 103 are removed by wet etching or the like. Subsequently, the insulating layers are formed inside the openings op.

### Effects

As described with reference to FIG. 1, the semiconductor memory device according to the embodiment includes the global bit lines GBL, a plurality of the bit lines BL electrically connected to the global bit lines GBL, and a plurality of the transistors TrB electrically connected between them. The gate electrodes of these plurality of the transistors TrB are connected to a plurality of the bit line select lines LB0 to LB2 disposed corresponding to the word lines WL0 to WL2. With this configuration, for example, as described with reference to FIG. 2, in the read operation and the like, it is possible to selectively electrically conduct only the bit line BL as the target of the read operation to the global bit line GBL and to electrically separate the other bit lines BL from the global bit lines GBL. Accordingly, electrostatic capacities of the global bit lines GBL can be reduced to ensure speed-up of the operation of the semiconductor memory device.

As described with reference to FIG. 8 to FIG. 10, in the semiconductor memory device according to the embodiment, each of the semiconductor layers 114 is opposed to the upper surface, the lower surface, and the side surfaces in the Y-direction of the conductive layer 112.

In this configuration, the channel is formed at the portion opposed to the upper surface, the portion opposed to the lower surface, and the portions opposed to the side surfaces in the Y-direction of the conductive layer 112 in the semiconductor layer 114. Therefore, the ON current of the transistors TrC, TrB can be relatively increased. Accordingly, the speed-up and the stabilization of the operation can be ensured.

In this configuration, the two transistors TrC, TrB mutually adjacent in the Z-direction are mutually adjacent via their respective channel regions. In this configuration, for example, the electrostatic capacity between the gate electrodes can be reduced compared with a structure in which the two transistors TrC, TrB mutually adjacent in the Z-direction are mutually adjacent via their respective gate electrodes. Accordingly, the speed-up and the stabilization of the operation can be ensured.

As described with reference to FIG. 12 to FIG. 66, the transistor TrB according to the embodiment is manufacturable collectively with the transistor TrC in the memory cell MC. Therefore, the manufacture is allowed almost without increase of manufacturing cost.

### Second Embodiment

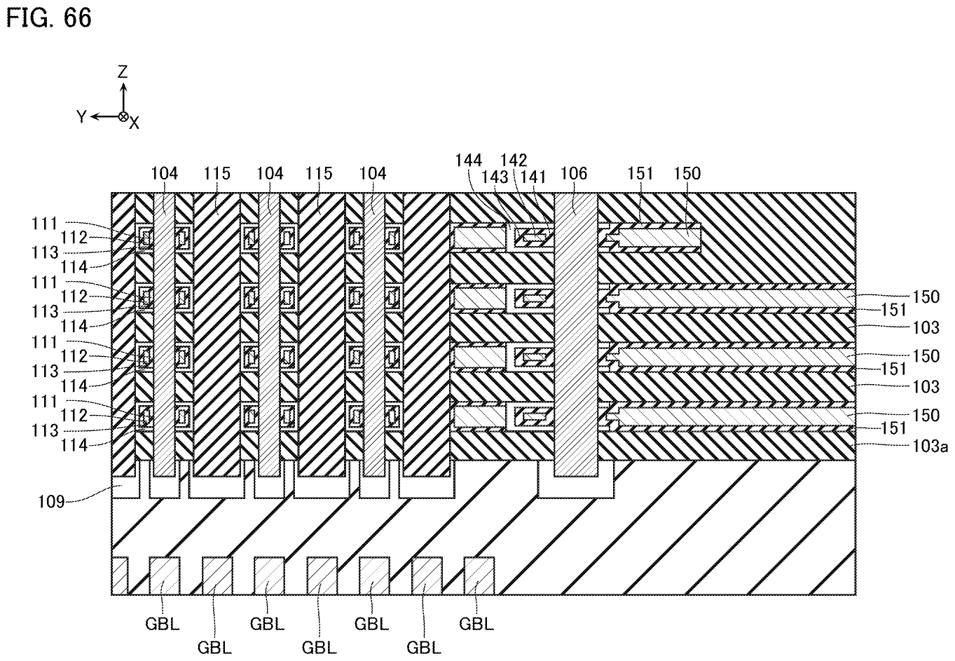

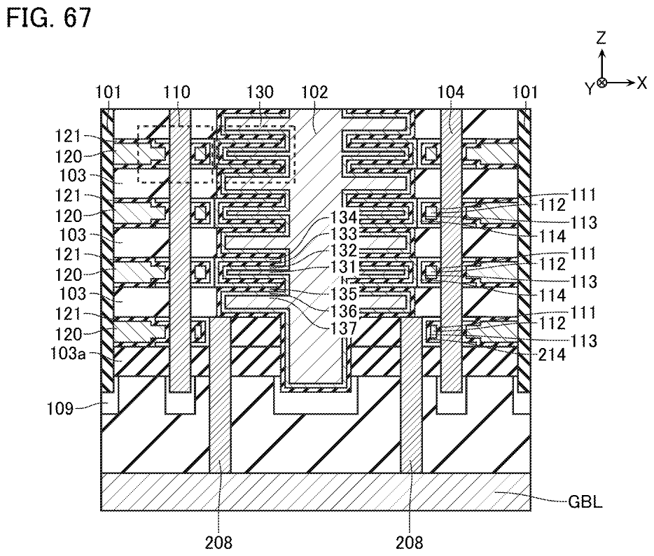

FIG. 67 is a schematic X-Z cross-sectional view illustrating a part of a configuration of a semiconductor memory device according to the second embodiment.

In the semiconductor memory device according to the first embodiment, the transistor layer TL is configured similarly to the memory layers ML0 to ML2. For example, in the first embodiment, the conductive layer 134 is disposed to not only the memory layers ML0 to ML2 but also the transistor layer TL. This conductive layer 134 functions as the source electrode of the transistor TrB. The lower surface of this conductive layer 134 is connected to the contact electrode 108.

However, this configuration is merely an example, and the structure of the transistor layer TL is adjustable, as necessary.

For example, the semiconductor memory device according to the second embodiment is configured approximately similarly to the semiconductor memory device according to the first embodiment. However, for example, as illustrated in FIG. 67, in the second embodiment, the transistor layer TL does not include the conductive layer 134. Additionally, in the second embodiment, the transistor layer TL includes semiconductor layers 214 instead of the semiconductor layers 114. The semiconductor layer 214 is basically configured similarly to the semiconductor layer 114. However, the semiconductor layer 214 has a side surface in the conductive layer 102 side in the X-direction connected to not the conductive layer 134 but a part of an outer peripheral surface of a contact electrode 208. The contact electrode 208 is configured approximately similarly to the contact electrode 108.

### Manufacturing Method

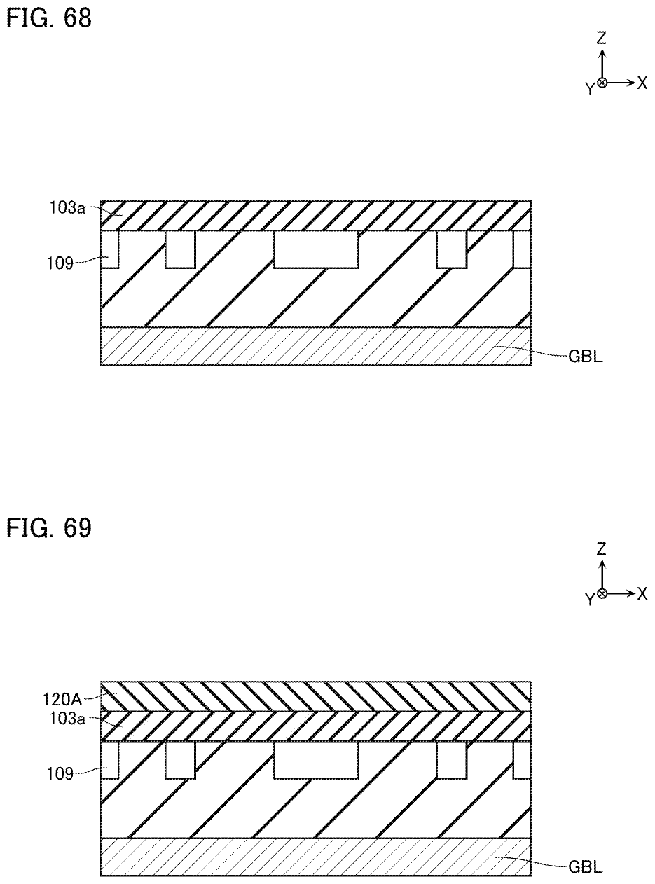

FIG. 68 to FIG. 74 are schematic cross-sectional views for describing a method for manufacturing the semiconductor memory device according to the second embodiment. FIG. 68 to FIG. 74 each illustrate a cross-sectional surface corresponding to that of FIG. 67.

In the manufacturing method, for example, as illustrated in FIG. 68, a plurality of the global bit lines

GBL, the etching stoppers 109, the insulating layer 103a, and the like are formed. This process is performed by photolithography, etching, or the like.

Next, for example, as illustrated in FIG. 69, one layer of the sacrifice layer 120A is formed. This process is performed by CVD or the like.

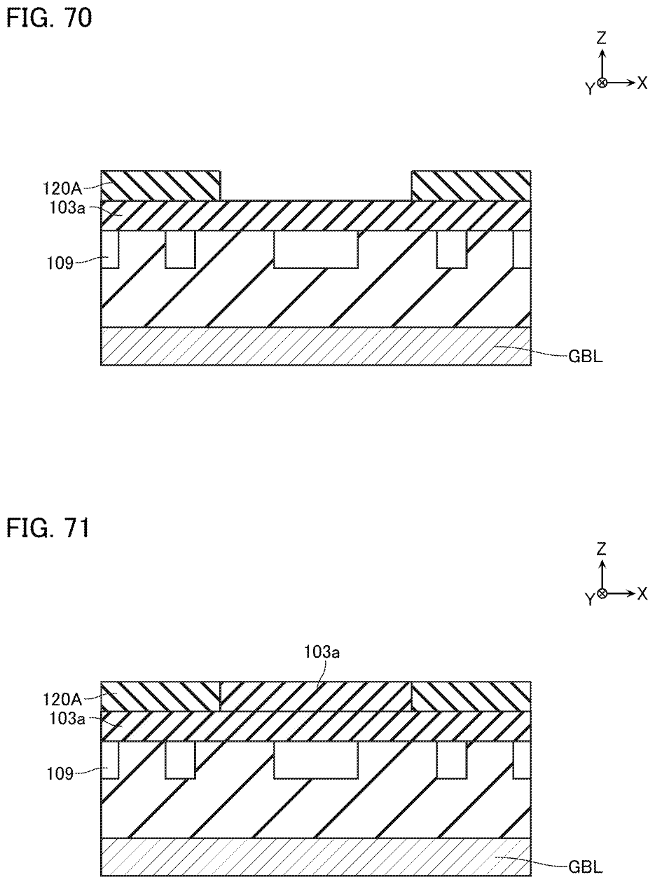

Next, for example, as illustrated in FIG. 70, a part of the sacrifice layer 120A is removed at the proximity of a region corresponding to the conductive layer 102. This process is performed by wet etching or the like.

Next, for example, as illustrated in FIG. 71, the insulating layer 103a is formed in the region at which the sacrifice layer 120A is removed. This process is performed by CVD or the like.

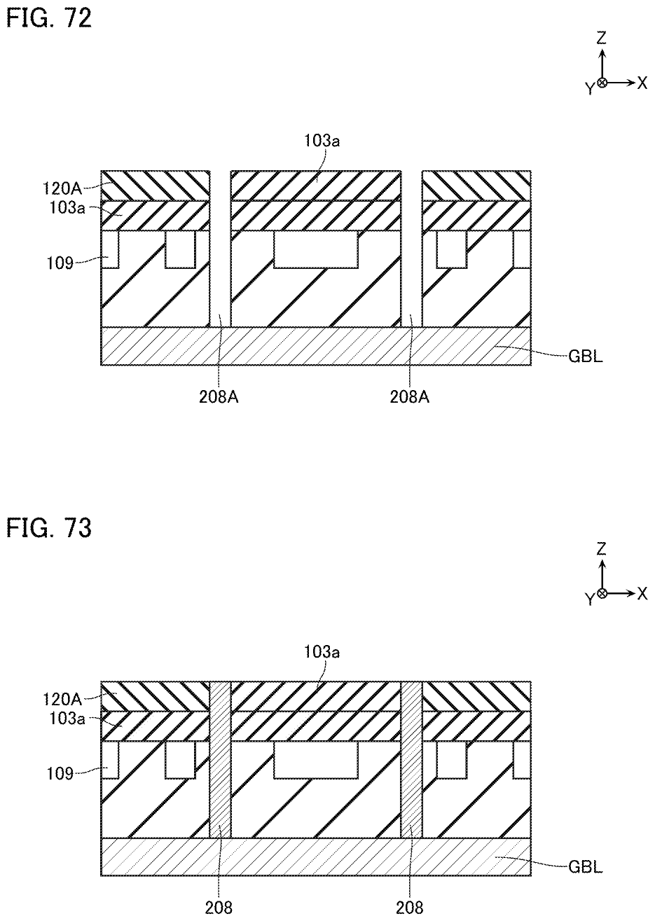

Next, for example, as illustrated in FIG. 72, openings 208A are formed at positions corresponding to the contact electrodes 208. The openings 208A extend in the Z-direction as illustrated in FIG. 72 to expose the upper surfaces of the global bit lines GBL. This process is performed by RIE or the like.

Next, for example, as illustrated in FIG. 73, the contact electrodes 208 are formed. This process is performed by CVD or the like.

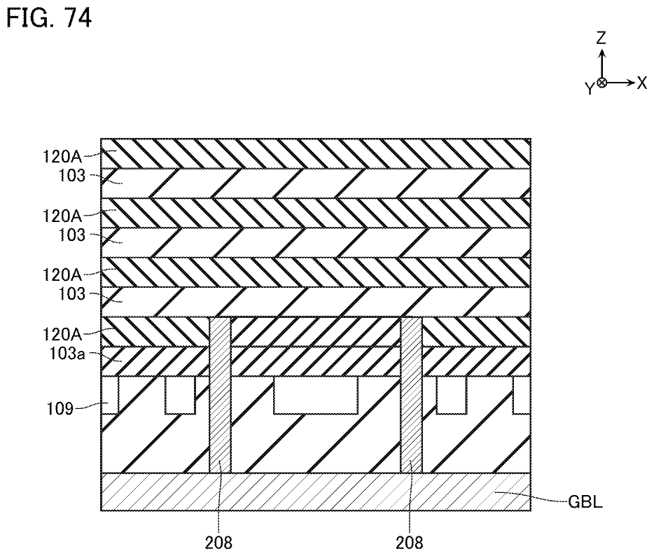

Next, for example, as illustrated in FIG. 74, a plurality of the insulating layers 103 and a plurality of the sacrifice layers 120A are alternately formed. This process is performed by CVD or the like.

Subsequently, the processes after the process described with reference to FIG. 13 in the manufacturing process of the semiconductor memory device according to the first embodiment are executed.

### Other Embodiments

The semiconductor memory devices according to the first embodiment and the second embodiment have been described above. However, the semiconductor memory devices according to these embodiments are merely examples, and the specific configuration, operation, and the like are adjustable, as necessary.

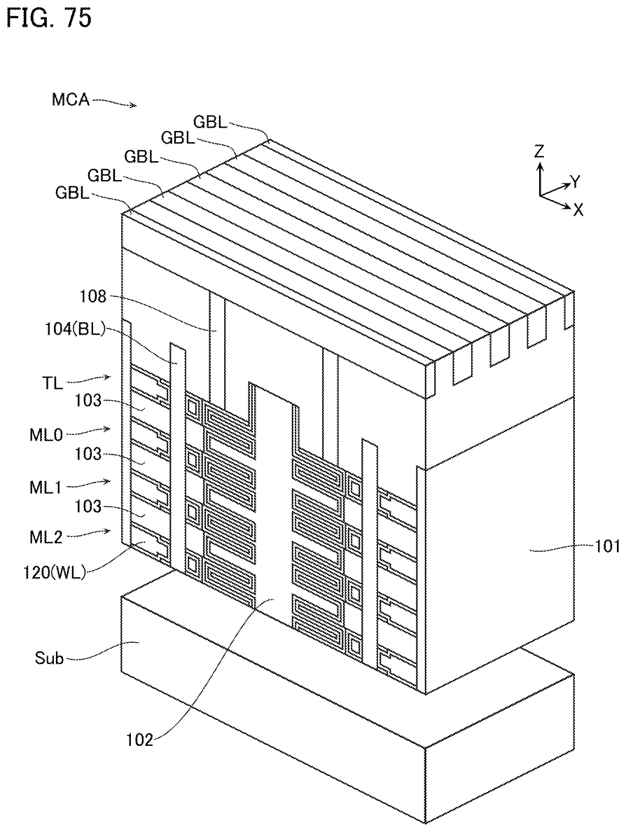

For example, in the semiconductor memory devices according to the first embodiment and the second embodiment, the global bit lines GBL are disposed below the memory layers ML0 to ML2. However, this configuration is merely an example, and the specific configuration is adjustable, as necessary. For example, as illustrated in FIG. 75, the global bit lines GBL may be disposed above the memory layers ML0 to ML2. In this case, the transistor layer TL and the contact electrodes 108 also may be disposed above the memory layers ML0 to ML2. In this case, the contact electrode 108 may be connected to the lower surface of the global bit line GBL at its upper end. The contact electrode 108 may be connected to the upper surface of the conductive layer 134 in the transistor layer TL at its lower end.

As described above, in the semiconductor memory devices according to the first embodiment and the second embodiment, the sense amplifier circuit is disposed in the region immediately below the memory cell array MCA in the upper surface of the semiconductor substrate Sub. In this configuration, the global bit lines GBL are disposed below the memory layers ML0 to ML2 to reduce a wiring capacity between the sense amplifier circuit and the memory layers ML0 to ML2, thereby allowing the execution of the read operation and the like at high speed. Similarly, for example, in a case where the sense amplifier circuit is disposed above the memory cell array MCA, the global bit lines GBL are disposed above the memory layers ML0 to ML2 to reduce the wiring capacity between the sense amplifier circuit and the memory layers ML0 to ML2, thereby allowing the execution of the read operation and the like at high speed. For example, in a case where the memory cell array MCA and the sense amplifier circuit are formed on different substrates and these two substrates are bonded, the sense amplifier circuit is disposed above the memory cell array MCA in some cases.

In the above description, the structure in which the two transistors TrC, TrB mutually adjacent in the Z-direction are mutually adjacent via their respective channel regions is employed. However, for example, a structure in which the two transistors TrC, TrB mutually adjacent in the Z-direction are mutually adjacent via their respective gate electrodes may be employed.

In the above description, the example in which the capacitor CpC is employed as the memory unit connected to the transistor structure 110 is described. However, the memory unit does not need to be the capacitor CpC. For example, the memory unit may be one that contains a ferroelectric material, a ferromagnet material, a chalcogen material such as GeSbTe, or another material and stores data using the characteristics of these materials. For example, in any of the structures described above, any of these materials may be included in the insulating layer between the electrodes forming the capacitor CpC.

### Others

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a plurality of memory layers arranged in a first direction intersecting with a surface of the substrate;
a first wiring disposed at a position closer to the substrate than the plurality of memory layers or a position farther from the substrate than the plurality of memory layers;
a transistor layer disposed between the plurality of memory layers and the first wiring; and
a second wiring that extends in the first direction and is connected to the plurality of memory layers and the transistor layer, wherein
each of the plurality of memory layers includes:
a memory unit;
a first semiconductor layer electrically connected between the memory unit and the second wiring;
a first electrode opposed to the first semiconductor layer;
a third wiring that extends in a second direction intersecting with the first direction and is connected to the first electrode;
a second semiconductor layer electrically connected to one end portion in the second direction of the third wiring; and
a second electrode opposed to the second semiconductor layer, and
the transistor layer includes:
a third semiconductor layer electrically connected between the first wiring and the second wiring; and
a third electrode opposed to the third semiconductor layer.

2. The semiconductor memory device according to claim 1, wherein
each of the plurality of memory layers includes:
a fourth semiconductor layer electrically connected to the other end portion in the second direction of the third wiring; and
a fourth electrode opposed to the fourth semiconductor layer.

3. The semiconductor memory device according to claim 1, wherein
the transistor layer includes:
a fourth wiring that extends in the second direction and is connected to the third electrode;
a fifth semiconductor layer connected electrically to one end portion in the second direction of the fourth wiring; and
a fifth electrode opposed to the fifth semiconductor layer.

4. The semiconductor memory device according to claim 3, wherein
the transistor layer includes:
a sixth semiconductor layer electrically connected to the other end portion in the second direction of the fourth wiring; and
a sixth electrode opposed to the sixth semiconductor layer.

5. The semiconductor memory device according to claim 1, wherein
the memory unit is a capacitor.

6. The semiconductor memory device according to claim 1, wherein
each of the first semiconductor layer and the third semiconductor layer contains an oxide semiconductor.

7. The semiconductor memory device according to claim 1, wherein
each of the first semiconductor layer and the third semiconductor layer contains at least one element of gallium (Ga) and aluminum (Al), and contains indium (In), zinc (Zn), and oxygen (O).

8. A semiconductor memory device comprising:
a substrate;
a plurality of memory layers arranged in a first direction intersecting with a surface of the substrate;
a first wiring disposed at a position closer to the substrate than the plurality of memory layers or a position farther from the substrate than the plurality of memory layers;
a transistor layer disposed between the plurality of memory layers and the first wiring;
a second wiring that extends in the first direction and is connected to the plurality of memory layers; and
a third wiring that extends in the first direction and is connected to the plurality of memory layers and the transistor layer, wherein
each of the plurality of memory layers includes:
a first electrode opposed to the second wiring;
a first semiconductor layer electrically connected between the first electrode and the third wiring; and
a second electrode opposed to the first semiconductor layer, and
the transistor layer includes:
a third electrode disposed at a position overlapping with the first electrode viewed in the first direction, the third electrode being electrically connected to the first wiring;
a second semiconductor layer electrically connected between the third electrode and the third wiring; and
a fourth electrode opposed to the second semiconductor layer.

9. The semiconductor memory device according to claim 8, wherein
the third electrode is opposed to the second wiring.

10. The semiconductor memory device according to claim 8, comprising
a contact electrode extending in the first direction, wherein
one end in the first direction of the contact electrode is electrically connected to the first wiring, and
the other end in the first direction of the contact electrode is electrically connected to a surface on one side in the first direction of the third electrode.

11. The semiconductor memory device according to claim 8, wherein
each of the first semiconductor layer and the second semiconductor layer contains an oxide semiconductor.

12. The semiconductor memory device according to claim 8, wherein
each of the first semiconductor layer and the second semiconductor layer contains at least one element of gallium (Ga) and aluminum (Al), and contains indium (In), zinc (Zn), and oxygen (O).

13. A semiconductor memory device comprising:
a substrate;
a plurality of memory layers arranged in a first direction intersecting with a surface of the substrate;
a first wiring disposed at a position closer to the substrate than the plurality of memory layers or a position farther from the substrate than the plurality of memory layers;
a transistor layer disposed between the plurality of memory layers and the first wiring; and
a second wiring that extends in the first direction and is connected to the plurality of memory layers and the transistor layer, wherein
each of the plurality of memory layers includes:
a memory unit;
a first semiconductor layer electrically connected between the memory unit and the second wiring; and
a first electrode opposed to the first semiconductor layer; and
the transistor layer includes:
a second semiconductor layer electrically connected between the first wiring and the second wiring; and
a second electrode opposed to the second semiconductor layer, and
the second semiconductor layer is opposed to surfaces on one side and the other side of the second electrode in the first direction.

14. The semiconductor memory device according to claim 13, wherein
the first semiconductor layer is opposed to surfaces on one side and the other side of the first electrode in the first direction.

15. The semiconductor memory device according to claim 13, wherein
when a cross-sectional surface that is perpendicular to the first direction and includes a part of one of a plurality of the first semiconductor layers is assumed to be a first cross-sectional surface,
the one of the plurality of the first semiconductor layers is opposed to surfaces on one side and the other side of the first electrode in a second direction in the first cross-sectional surface, and the second direction intersects with the first direction.

16. The semiconductor memory device according to claim 13, wherein
when a cross-sectional surface that is perpendicular to the first direction and includes a part of the second semiconductor layer is assumed to be a second cross-sectional surface,
the second semiconductor layer is opposed to surfaces on one side and the other side of the second electrode in a second direction in the second cross-sectional surface, and the second direction intersects with the first direction.

17. The semiconductor memory device according to claim 13, wherein
the memory unit is a capacitor.

18. The semiconductor memory device according to claim 13, wherein
each of the first semiconductor layer and the second semiconductor layer contains an oxide semiconductor.

19. The semiconductor memory device according to claim 13, wherein
each of the first semiconductor layer and the second semiconductor layer contains at least one element of gallium (Ga) and aluminum (Al), and contains indium (In), zinc (Zn), and oxygen (O).
